(19) United States
(12) Patent Application Publication
(10) Pub. No.: US 2025/0386575 A1
(43) Pub. Date: Dec. 18, 2025

(54) ISOLATION STRUCTURE IN SEMICONDUCTOR DEVICE AND MANUFACTURING METHODS THEREOF

(71) Applicant: Taiwan Semiconductor Manufacturing Company, Ltd., Hsin-Chu (TW)

(72) Inventors: Tzu-Ging LIN, Kaohsiung City (TW); Yun-Chen WU, Hsinchu (TW); Ryan Chia-Jen CHEN, Hsinchu (TW)

(21) Appl. No.: 18/941,913

(22) Filed: Nov. 8, 2024

Related U.S. Application Data
(60) Provisional application No. 63/658,946, filed on Jun. 12, 2024.

(51) Int. Cl. H01L 29/66; H01L 21/3065; H01L 21/762; H01L 21/8234; H01L 27/088; H01L 29/06; H01L 29/423; H01L 29/775; H01L 29/786

(52) U.S. Cl. CPC H10D 64/017; H01L 21/3065; H01L 21/76224; H10D 30/014; H10D 30/43; H10D 30/6735; H10D 30/6757; H10D 62/121; H10D 84/0128; H10D 84/013; H10D 84/0151; H10D 84/038; H10D 84/83

(57) ABSTRACT

A method of the present disclosure includes forming a stack that includes channel layers interleaved by sacrificial layers, patterning the stack to form a fin-shaped structure, forming a dummy gate stack over a first region of the fin-shaped structure, selectively removing the sacrificial layers to release the channel layers as channel members, depositing dielectric dummy layers in spaces between the channel members, forming a hard mask layer above the dummy gate stack, patterning the hard mask layer to form an opening directly above the first region of the fin-shaped structure, performing an etching process through the opening to remove the channel members and the dielectric dummy layers in the fin-shaped structure simultaneously, such that a second trench is formed through the dummy gate stack, and depositing an isolation structure in the second trench. The isolation structure divides the dummy gate stack into two segments.

### PRIORITY DATA

This application claims priority to U.S. Provisional Patent Application No. 63/658,946, filed on Jun. 12, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides.

As GAA devices continue to scale, various challenges have arisen. For example, to maintain the desired scaling and increased density for GAA devices in advanced technology nodes, a continuous poly on diffusion edge (CPODE) process may be employed to create an isolation structure (also referred to as a CPODE structure or a CPODE feature) that supports the continued reduction of the contacted poly pitch (CPP) (or “gate pitch”). Although existing isolation structures and fabrication techniques thereof have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2 illustrates a perspective view of a work-in-progress (WIP) structure, according to one or more aspects of the present disclosure.

FIGS. 3-39 illustrate fragmentary top and cross-sectional views of the WIP structure during a fabrication process according to the method of FIG. 1, according to one or more aspects of the present disclosure.

FIGS. 40-51 illustrate fragmentary cross-sectional views of various alternative embodiments of the WIP structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art.

The present disclosure is generally related to GAA transistors and manufacturing methods thereof. Embodiments of the present disclosure offer advantages over the existing art, though it is understood that other embodiments may offer different advantages, not all advantages are necessarily discussed herein, and no particular advantage is required for all embodiments. For example, embodiments discussed herein include isolation structures and related methods to isolate adjacent metal gate structures.

Continuing to provide the desired scaling and increased density for GAA devices in advanced technology nodes calls for scaling of the contacted poly pitch (CPP) (or “gate pitch”). In some embodiments of the present disclosure, a CPODE process is used to scale the CPP. The CPODE process may provide an isolation structure (also referred to as a CPODE structure or a CPODE feature) between neighboring gate structures, and thus neighboring transistors, by performing a selective etching process along an active edge (e.g., at a boundary of adjacent active regions) to form a cut region and filling the cut region with dielectric material(s). An active region includes a region where transistor structures are formed (e.g., including channel, source, and drain). In some examples, an active region may have a fin-like shape protruding from a substrate and may be disposed between insulating regions (e.g., shallow trench isolation (STI) regions). In some implementations, the CPODE feature is formed by filling a CPODE trench, which is formed by removing a portion of a dummy gate stack and corresponding one or more fin-shaped active regions thereunder. However, a replacement gate process may pose challenges in maintaining device integrity during the formation of the CPODE trench.

In a replacement gate process, a dummy gate stack is formed first as a placeholder and is subsequently replaced with a functional gate structure. In some replacement gate processes, sacrificial materials among nanostructures (also referred to as channel members) of the GAA transistor are removed after epitaxial source/drain features are formed. Ideally, due to the different material compositions, a large etch selectivity between the sacrificial materials (e.g., SiGe) and the nanostructures (e.g., Si) should have safeguarded the nanostructures from etching loss during the removal of the sacrificial materials. However, atoms other than silicon (e.g., Ge) in the sacrificial materials may diffuse into the nanostructures as impurities during annealing processes, such as the annealing processes in forming the epitaxial source/drain features. The diffusion of the impurities lowers the etching selectivity. As a result, the nanostructures may suffer from etching loss during the removal of the sacrificial materials. For example, top and bottom surfaces of the nanostructures may become non-flat and have a curvature profile due to extra etching loss. The curvature profile of the top and bottom surfaces of the nanostructures may cause gate structure profile variation and result in device performance non-uniformity.

To improve uniformity of the surface profiles of the nanostructures and gate structures, one way is to replace the sacrificial layers with a dielectric dummy layer that exhibits higher etching contrast with respect to the nanostructures prior to the replacement gate process. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. An inner spacer layer is deposited over the inner spacer recesses. The deposited inner spacer layer is etched back to form inner spacers. Source/drain features are then formed over the source/drain recesses. After selective removal of the dummy gate stack, the dielectric dummy layer is selectively removed to release the channel members again. A metal gate structure is then formed to wrap around each of the channel members. To improve the etching contrast, the dielectric dummy layer may be formed of an oxide. During the CPODE trench formation, if the dielectric dummy layer and the channel members are removed separately in two consecutive etching processes, the etchants targeting at the dielectric dummy layer may be difficult to flow into the space vertically between the channel members and consequently leave oxide residues therein. Further, since the dielectric dummy layer and the inner spacers are both dielectric materials, during the CPODE trench formation an etching process targeting at the dielectric dummy layer with a high selectivity may also damage the inner spacers. The damage of the inner spacers may lead to metal gate protrusion and cause a short circuit between subsequently-formed metal gate structure and adjacent source/drain features and contacts.

Embodiments of the present disclosure offer an etching process for the CPODE trench formation in which the channel members and the dielectric dummy layer are collectively removed in an anisotropic etching process with a low selectivity regarding the semiconductor material in the channel members and the dielectric material in the dielectric dummy layer. The low selectivity allows the dielectric dummy layer and the channel members to be removed at the same time without oxide residues left behind. The directivity of the etching process protects the inner spacers from damage. Thus, the integrity of the device features in proximity to the CPODE feature is improved.

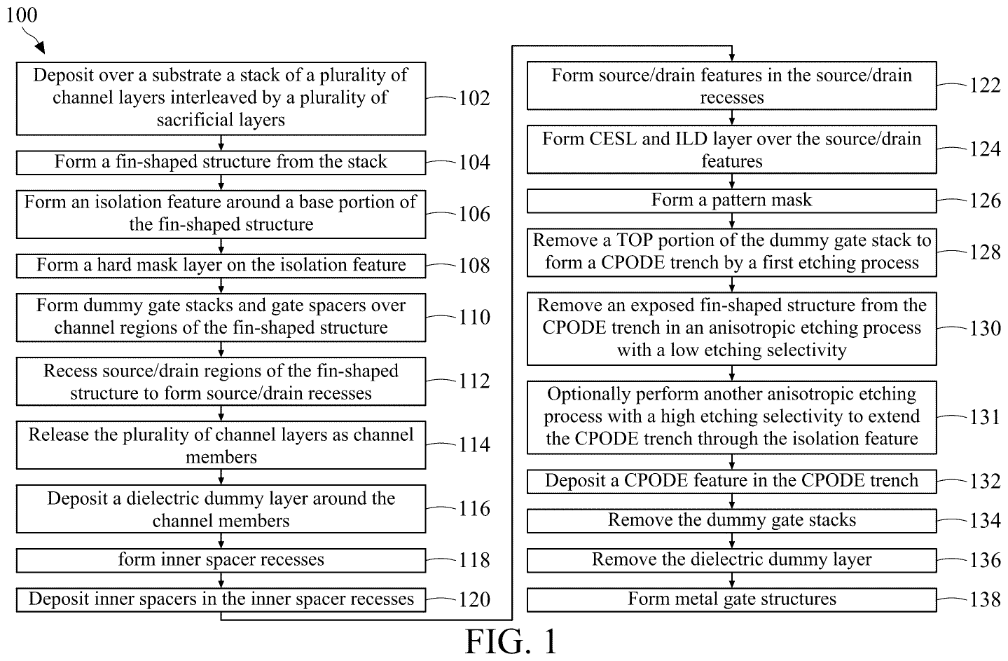

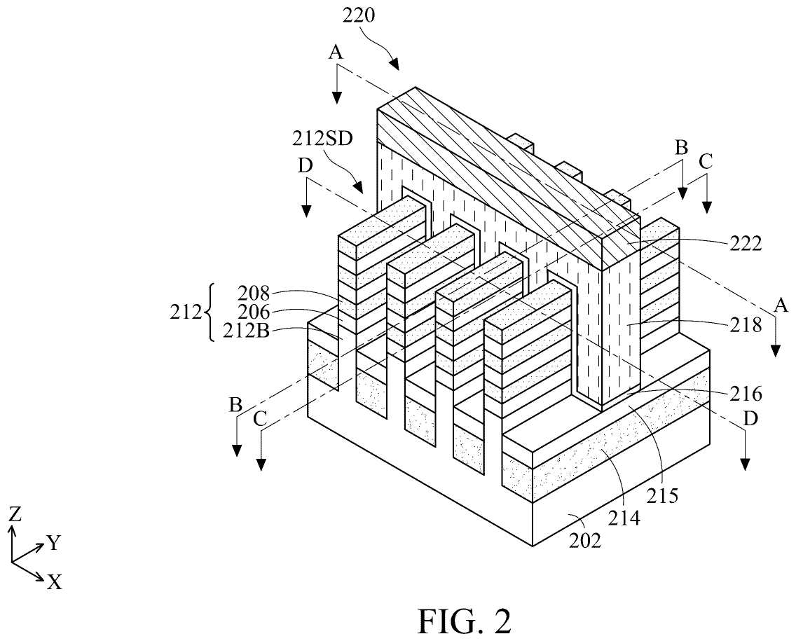

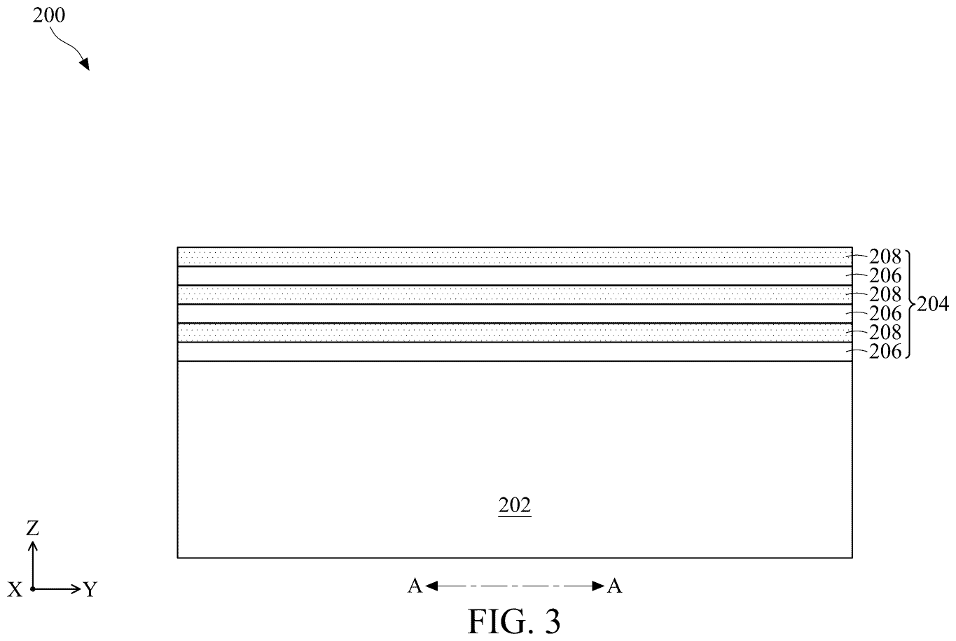

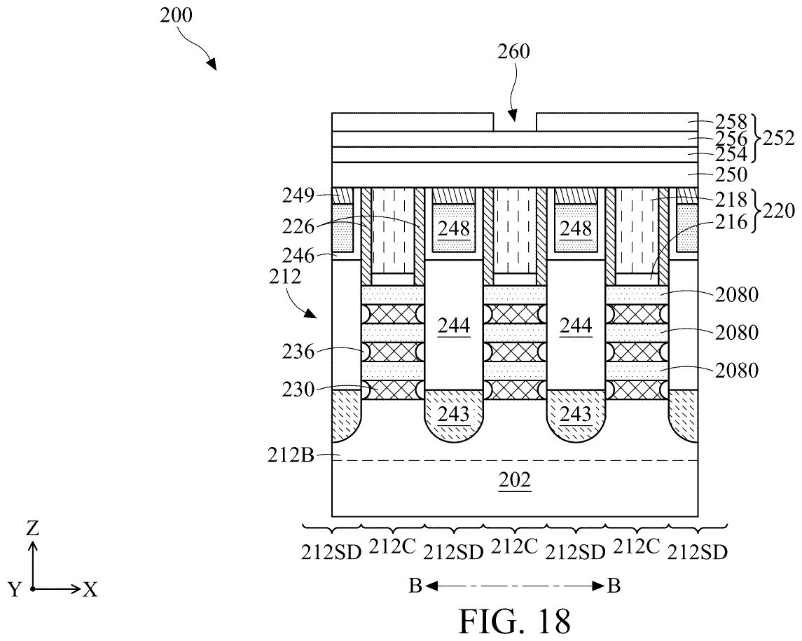

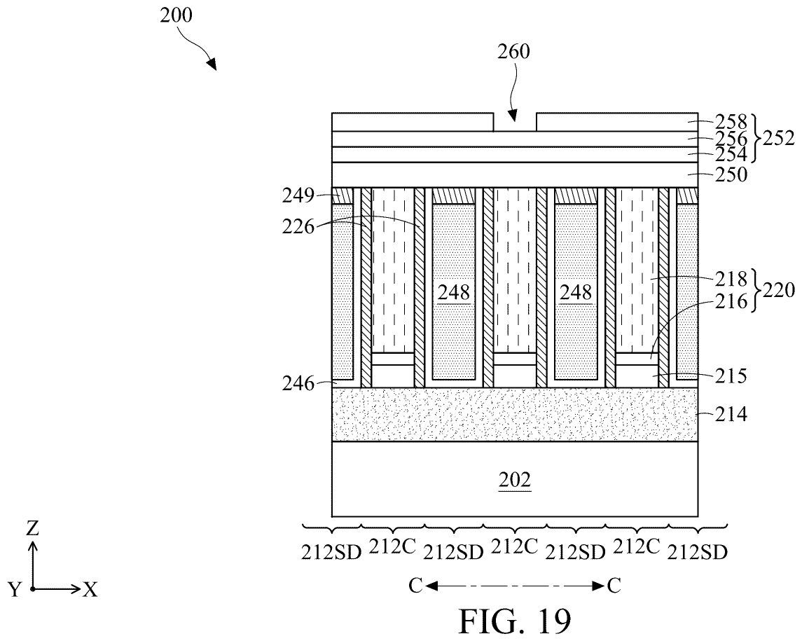

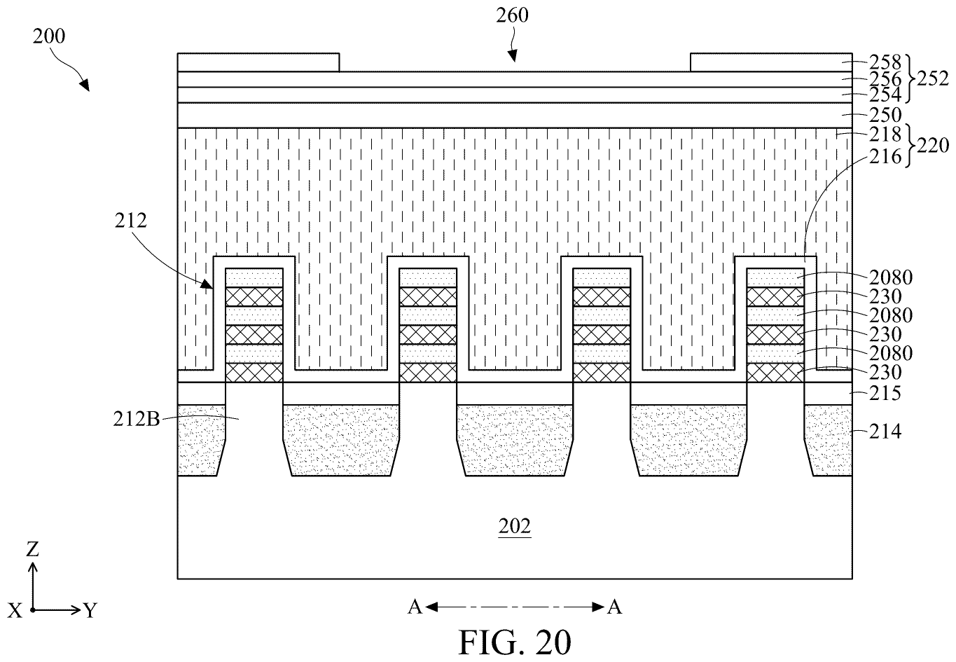

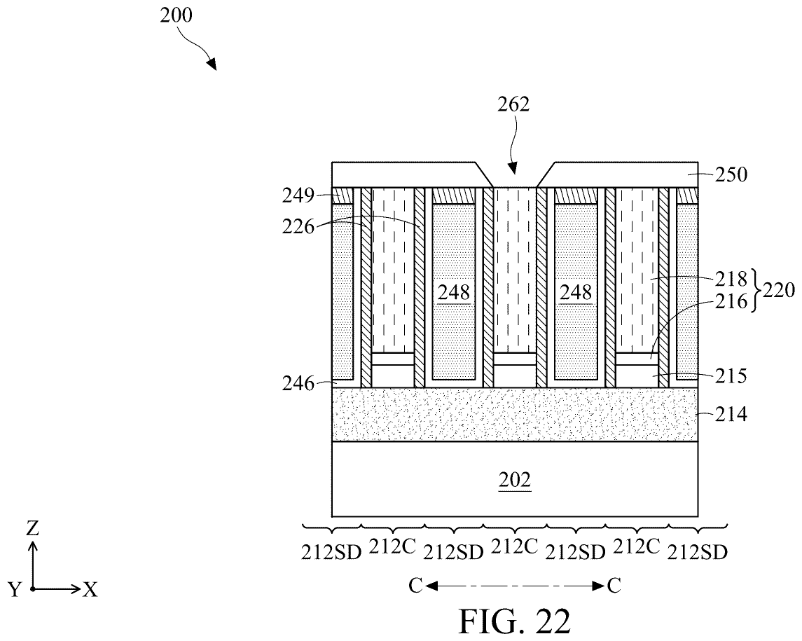

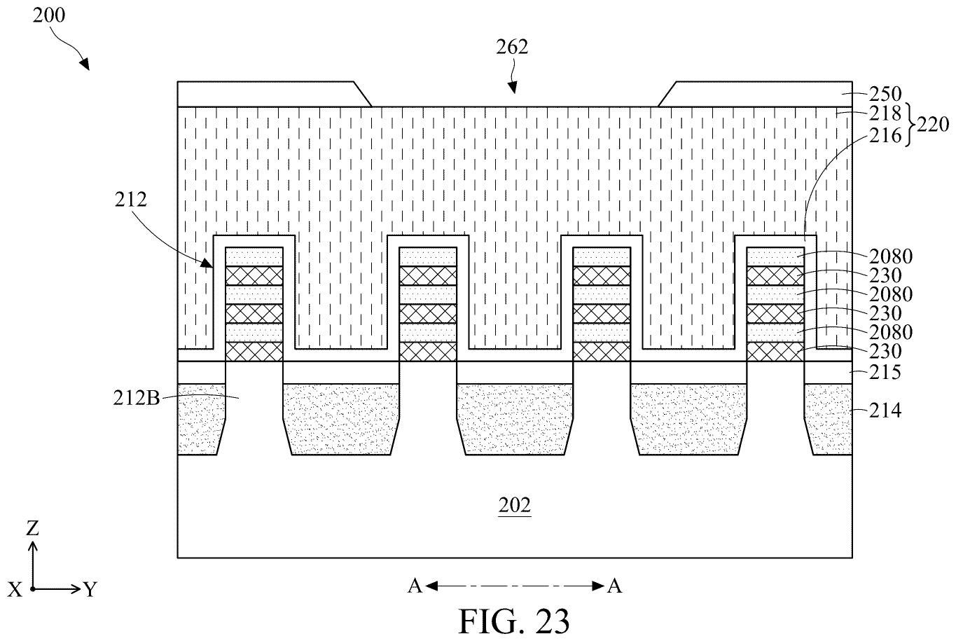

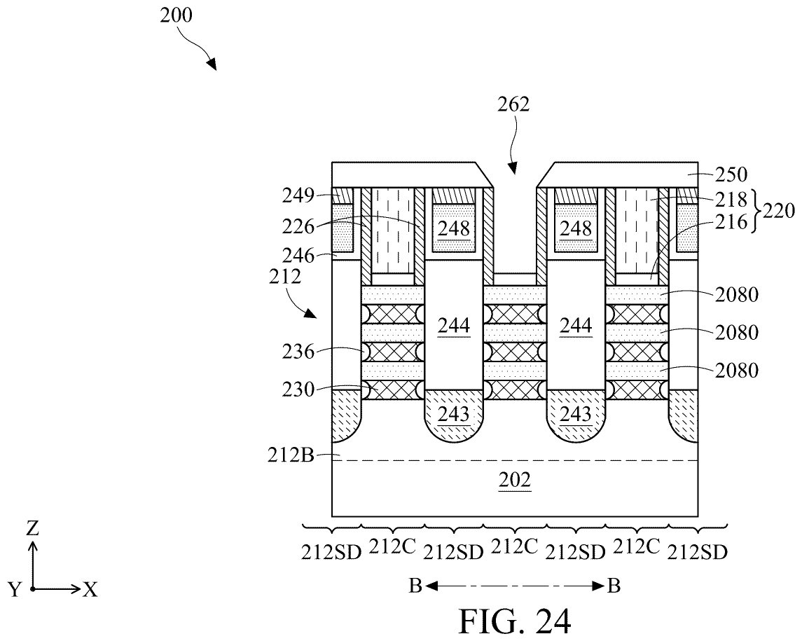

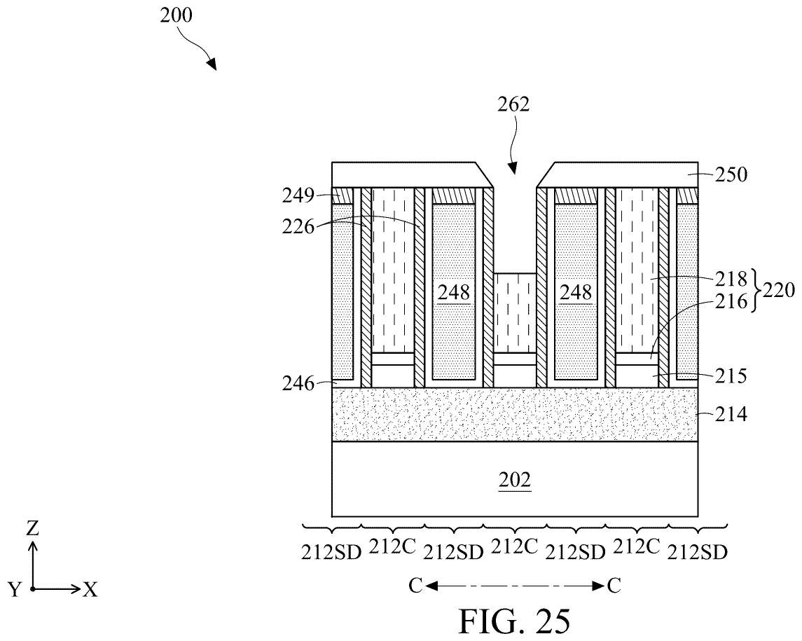

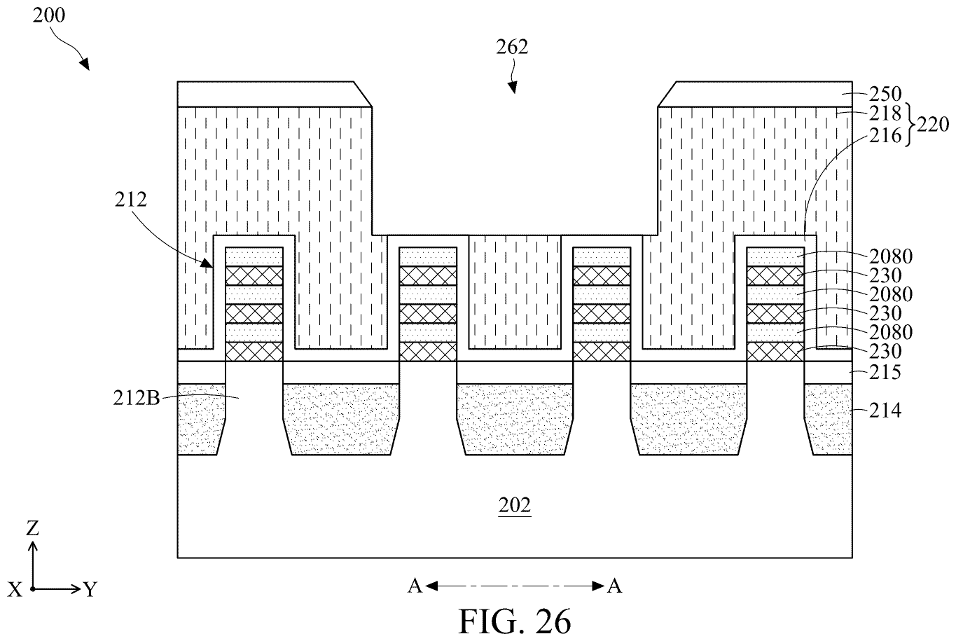

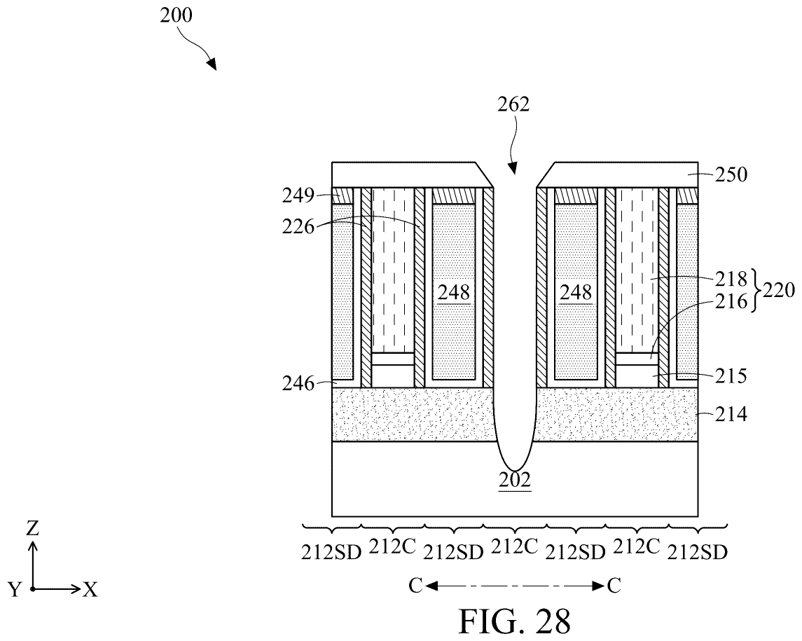

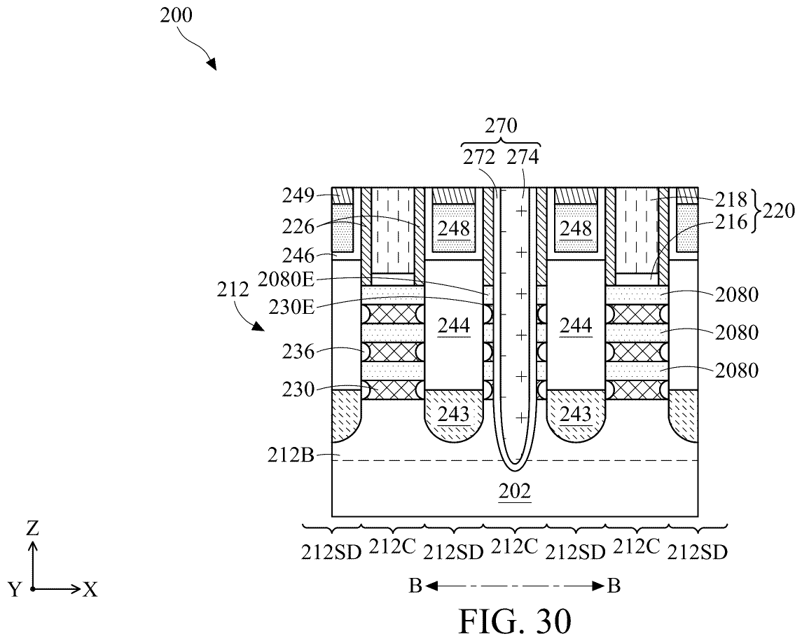

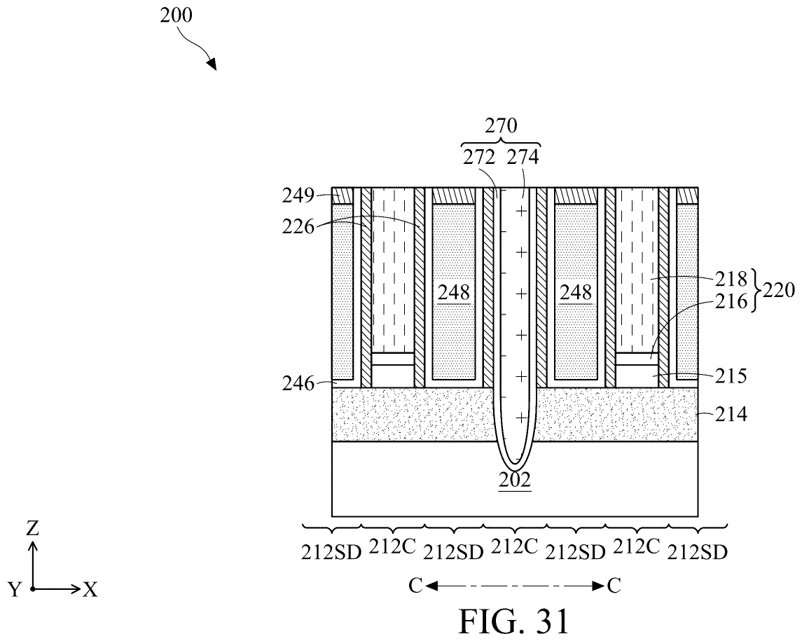

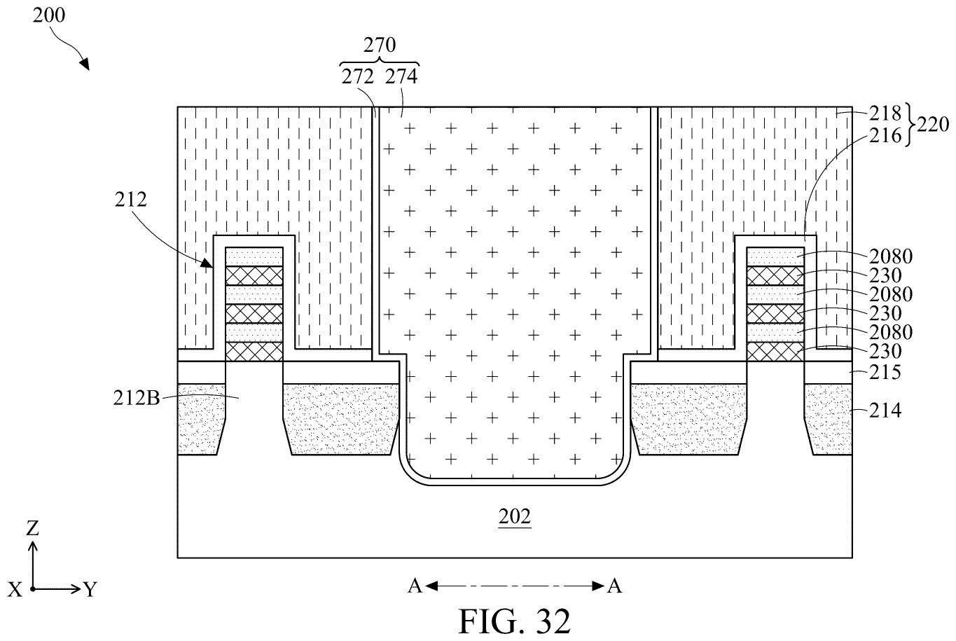

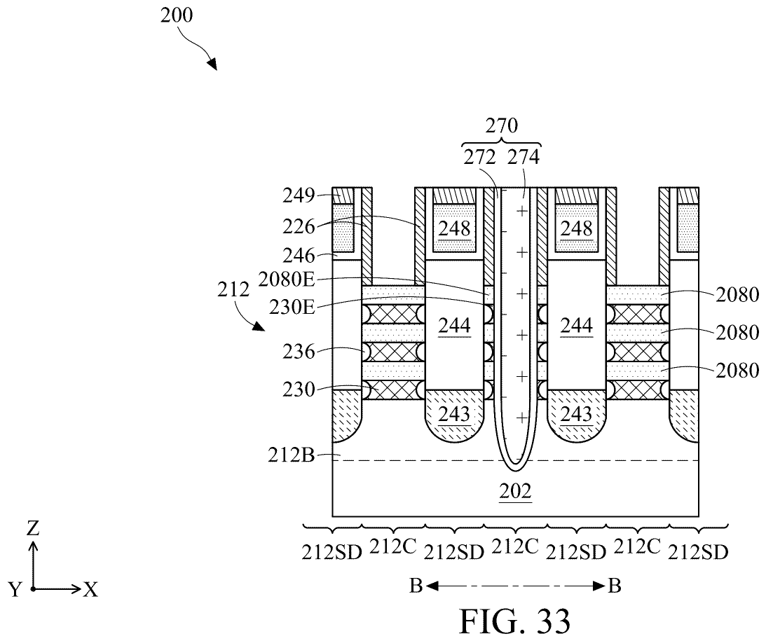

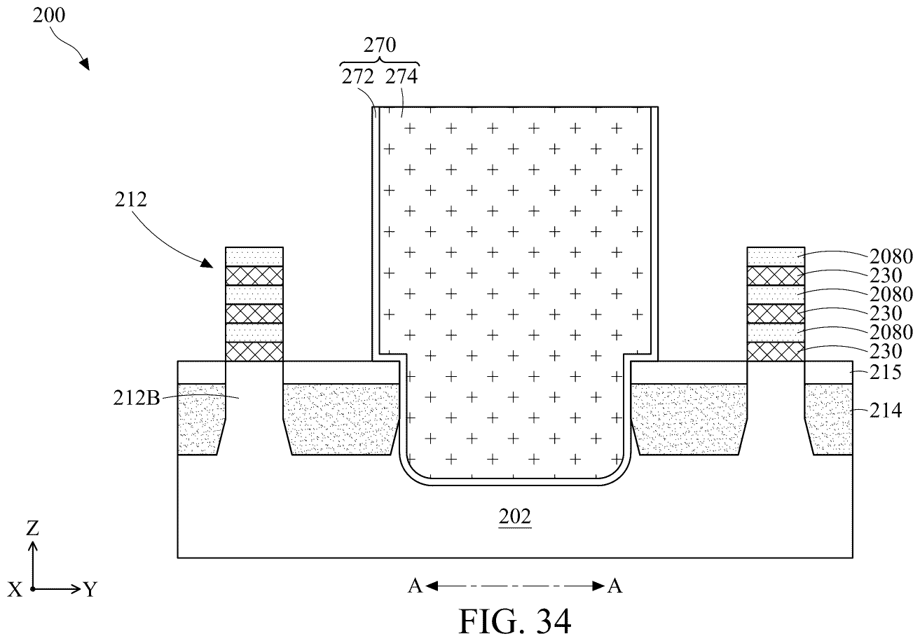

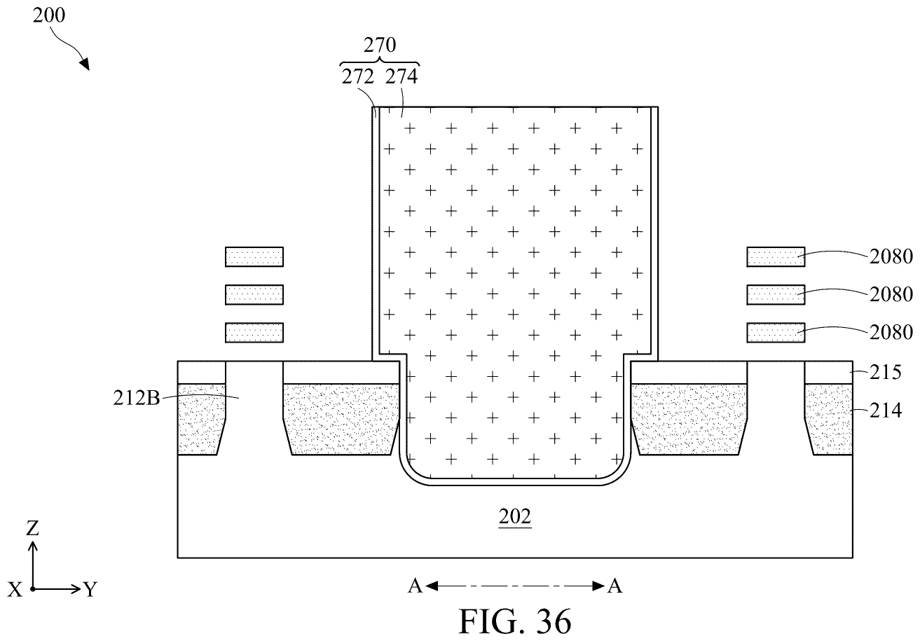

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-39. FIG. 2 is a perspective view of a WIP structure 200, and FIGS. 3-39 are fragmentary top and cross-sectional views (e.g., a cut along A-A, B-B, C-C, or D-D line as illustrated in FIG. 2) of the WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-39 are perpendicular to one another. Throughout the present disclosure, unless expressly described otherwise, like reference numerals denote like features or steps.

FIG. 2 illustrates an example of the semiconductor device 200 in a perspective view, in accordance with some embodiments. The semiconductor device 200 as illustrated in FIG. 1 is at a stage of fabrication that dummy gate stacks 220 are disposed across the fin-shaped structures 212. Each of the dummy gate stacks 220 includes a dummy dielectric layer 216, a dummy electrode layer 218, and a gate-top hard mask layer 222. The fin-shaped structures 212 protrude from a substrate 202. Each of the fin-shaped structures 212 include a fin-shaped base 212B, and an epitaxial stack of channel layers 208 and sacrificial layers 206 interleaved in a vertical direction. The channel layers 208 in the form of nanostructures (e.g., nanosheets or nanowires) are interleaved with the sacrificial layers 206. Source/drain regions 212SD are defined on opposing sides of the dummy gate stacks 220. An isolation feature 214 and a hard mask layer 215 atop are formed on opposing sides of the fin-shaped structures 212.

FIG. 2 further illustrates reference cross-sections that are used in later figures. Cross-section A-A is along a longitudinal axis of the dummy gate stacks 220 and in a direction, for example, perpendicular to the direction of current flow between the source/drain regions 212SD of the respective GAA transistors of the semiconductor device 200. Cross-section B-B is perpendicular to cross-section A-A and is along a longitudinal axis of the fin-shaped structure 212 and in a direction of, for example, a current flow between the source/drain regions 212SD of the respective GAA transistors of the semiconductor device 200. Cross-section C-C is parallel to cross-section B-B and between two neighboring fin-shaped structures 212. Cross-section D-D is parallel to cross-section A-A and extends through source/drain regions 212SD of the semiconductor device 200. Subsequent figures may refer to these reference cross-sections for clarity.

Referring to FIGS. 1 and 3, method 100 includes a block 102 where a stack 204 of alternating semiconductor layers is formed over the semiconductor device 200. As shown in FIG. 3, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, Ge % in the sacrificial layers 206 may be not less than about 20%, such as about 30% or above. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

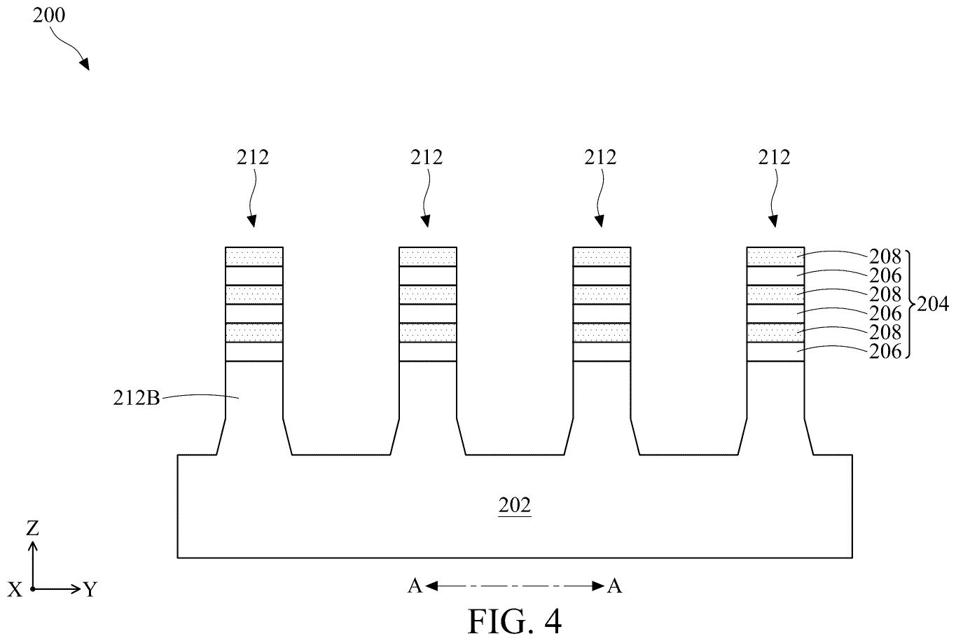

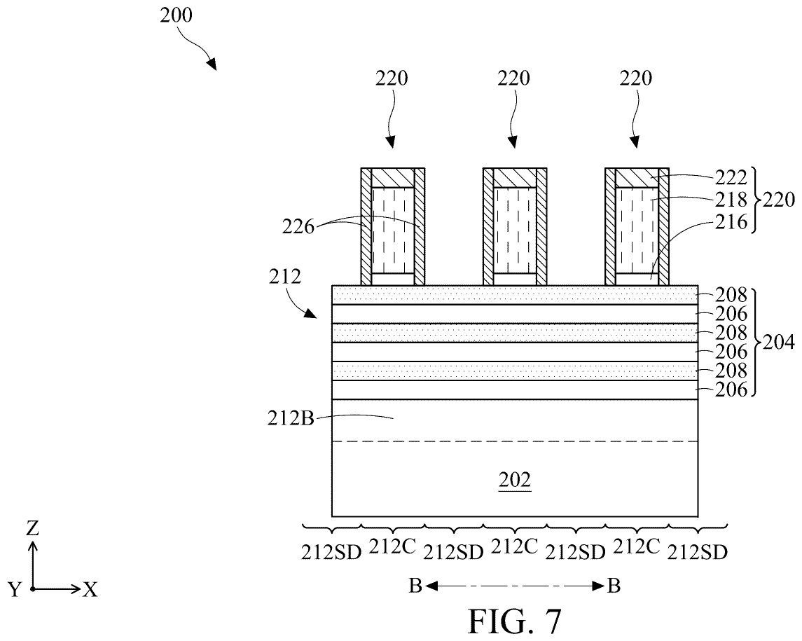

Referring to FIGS. 1 and 4, method 100 includes a block 104 where fin-shaped structures 212 are formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structures 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 4, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 extends vertically along the Z direction and lengthwise along the Y direction. The fin-shaped structure 212 provides an active region (also termed as active region 212) for the subsequently-formed transistors, which includes channel regions (denoted as 212C, as shown in FIG. 7) and source/drain regions (denoted as 212SD, as shown in FIG. 7). As shown in FIG. 4, the fin-shaped structure 212 includes a fin-shaped base 212B patterned from the substrate 202 and the patterned stack 204 disposed directly over the fin-shaped base 212B. In the illustrated embodiment as shown in FIG. 3, the patterned stack 204 and the top portion of the fin-shaped base 212B have substantially straight sidewalls; while the bottom portion of the fin-shaped base 212B has tapering sidewalls due to loading effect during the patterning process.

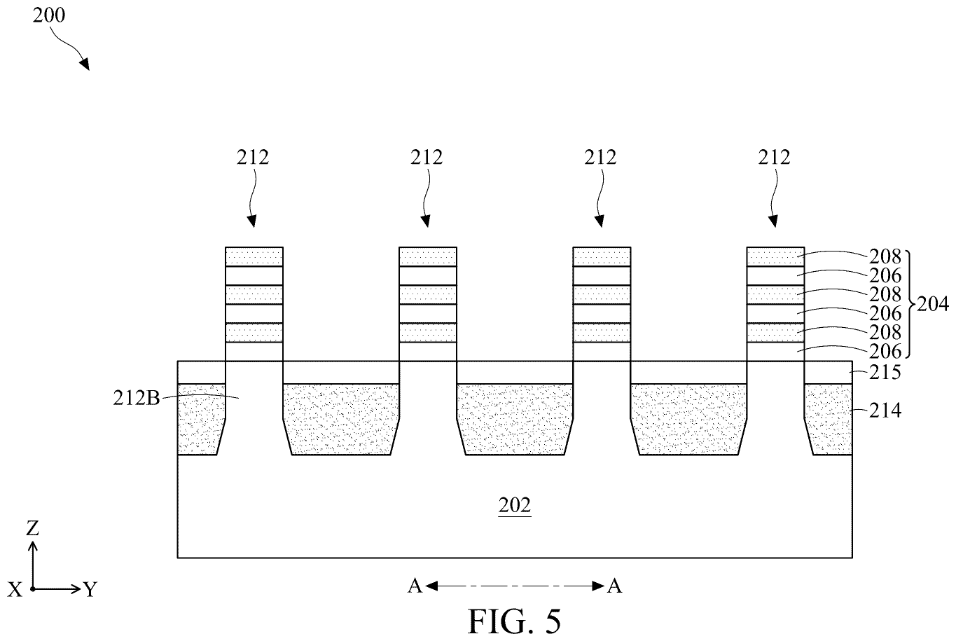

Referring to FIGS. 1 and 5, method 100 includes a block 106 where an isolation feature 214 is formed around the fin-shaped base 212B of the fin-shaped structures 212. In some embodiments represented in FIG. 5, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214 or an STI region 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation feature 214 shown in FIG. 5. The fin-shaped structure 212 rises above the isolation feature 214 after the recessing, while the fin-shaped base 212B is embedded or buried in the isolation feature 214.

Still referring to FIGS. 1 and 5, method 100 includes a block 108 where a hard mask layer 215 is formed over the STI feature 214 and around a top portion of the fin-shaped base 212B. A composition of the hard mask layer 215 is different from a composition of the STI feature 214 to ensure that each one of them may be selectively etched without substantially damaging the other one. In some embodiments, the STI feature 214 includes an oxide, and the hard mask layer 215 includes a nitride (e.g., silicon nitride) or an oxynitride (e.g., silicon oxynitride). By way of example, in some embodiments, a nitride-containing material is first deposited over the STI feature 214, filling the trenches with nitride. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the hard mask layer 215. The fin-shaped structure 212 rises above the hard mask layer 215 after the recessing, while the fin-shaped base 212B is embedded or buried in the combination of the STI feature 214 and the hard mask layer 215. The STI feature 214 and the hard mask layer 215 may also be collectively considered as layers of a multi-layer isolation feature.

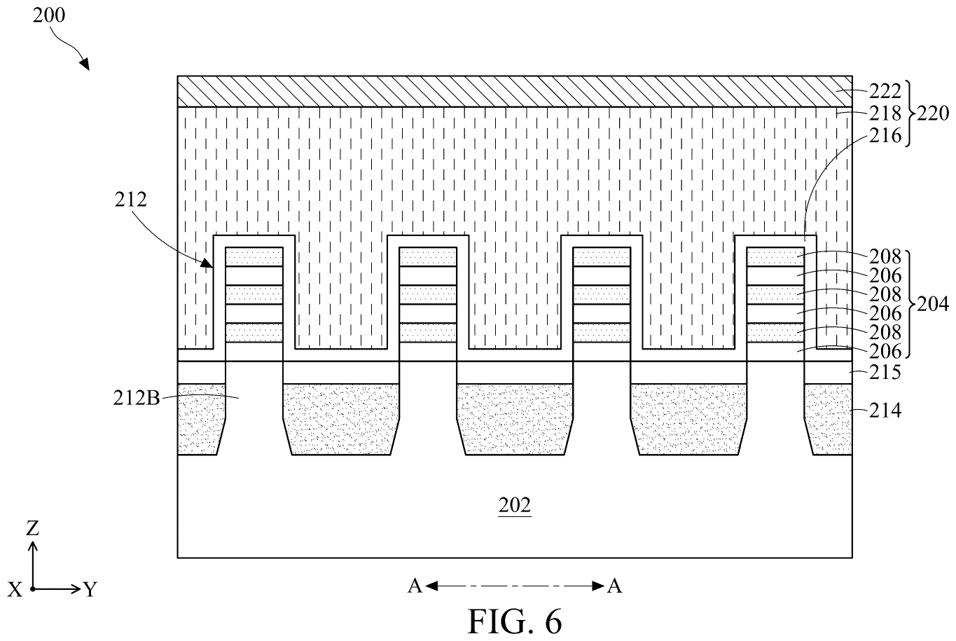

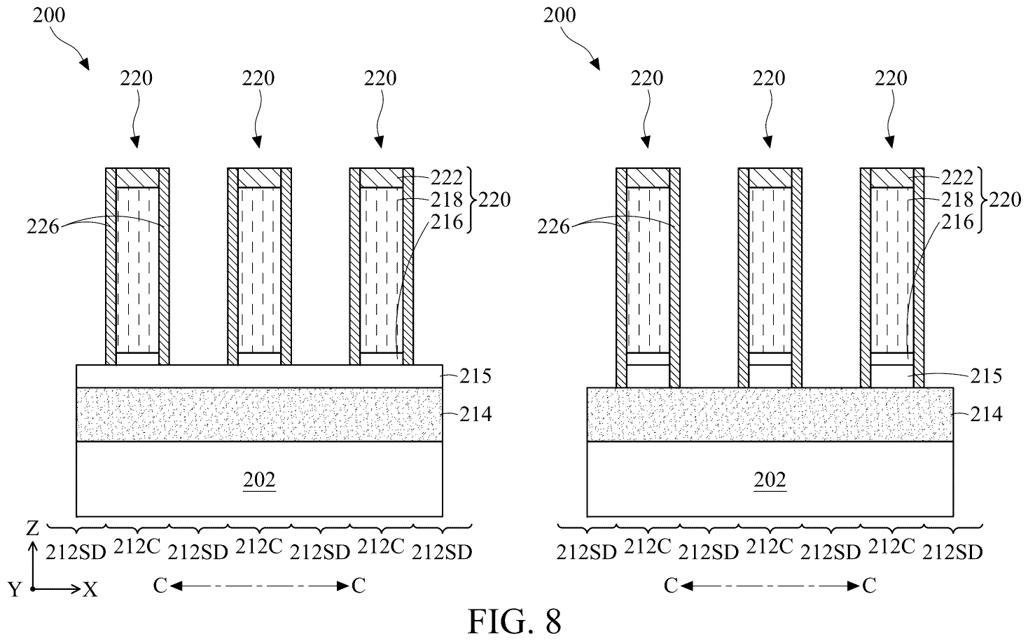

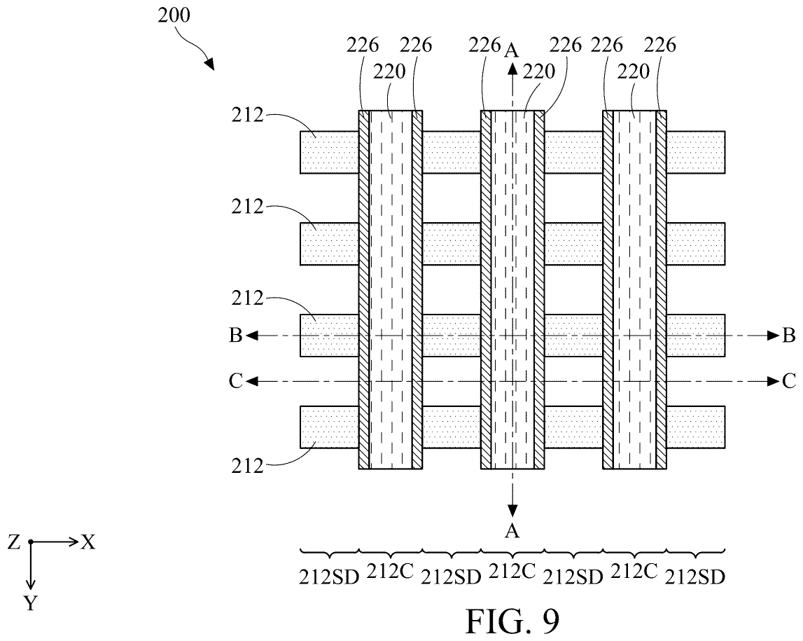

Referring to FIGS. 1 and 6-9, method 100 includes a block 110 where dummy gate stacks 220 and gate spacers 226 are formed over channel regions 212C of the fin-shaped structure 212. The dummy gate stacks 220 serve as a placeholder to undergo various processes and are to be removed and replaced by functional gate structures. Other processes and configuration are possible. FIG. 9 is a fragmentary top view of the semiconductor device 200 at the conclusion of block 110, FIG. 6 is a cross-sectional view along the A-A line in FIG. 9 (also the A-A line in FIG. 2), FIG. 7 is a cross-sectional view along the B-B line in FIG. 9 (also the B-B line in FIG. 2), and FIG. 8 is a cross-sectional view along the C-C line in FIG. 9 (also the C-C line in FIG. 2). As shown in FIG. 7, the dummy gate stacks 220 and gate spacers 226 are formed over the fin-shaped structure 212, and the fin-shaped structure 212 may be divided into channel regions 212C underlying the dummy gate stacks 220 and the gate spacers 226 and source/drain regions 212SD that do not underlie the dummy gate stacks 220 and the gate spacers 226. The channel regions 212C are adjacent to the source/drain regions 212SD. As shown in FIG. 7, the channel region 212C is disposed between two source/drain regions 212SD along the X direction. As used herein, a source/drain region, or “S/D region,” may refer to a region that provides a source and/or drain for one or multiple devices. It may also refer to a source or a drain of one or multiple devices. Also, in FIG. 5 (as well as in following figures showing the cross-sectional view in the X-Z plane), a horizontal dotted line marks the position of the bottom surface of the isolation feature 214. In the depicted embodiment as shown in the right-side figure in FIG. 8, the patterning of the dummy gate stacks 220 also patterns the hard mask layer 215. The gate spacers 226 covers sidewalls of the patterned hard mask layer 215. Alternatively, the hard mask layer 215 may remain intact during the patterning of the dummy gate stacks 220 depending on the etchants applied, such as the depicted embodiment as shown in FIG. 2 and the left-side figure in FIG. 8. In the following figures, for the sake of simplicity, the manufacturing operations after the structure shown in the right-side figure in FIG. 8 is formed are explained. However, the same operations can be applied to the structure shown in the left-side figure in FIG. 8.

The formation of the dummy gate stack 220 may include deposition of layers in the dummy gate stack 220 and patterning of these layers. Referring to FIG. 6, a dummy dielectric layer 216, a dummy electrode layer 218, and a gate-top hard mask layer 222 may be blanketly deposited over the semiconductor device 200. The dummy dielectric layer 216 may be conformally deposited on the fin-shaped structure 212 using a chemical vapor deposition (CVD) process, an atomic layer deposition (ALD) process, an oxygen plasma oxidation process, or other suitable processes. The term “conformally” may be used herein for ease of description of a layer having substantially uniform thickness over various regions. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stacks 220, as shown in FIG. 7. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 is a bi-layer structure, which may include a silicon oxide layer and a silicon nitride layer over the silicon oxide layer.

The formation of the gate spacers 226 may include deposition of a gate spacer layer and etching back the gate spacer layer. In some embodiments, the gate spacer layer is deposited conformally over the semiconductor device 200, including over top surfaces and sidewalls of the dummy gate stacks 220. The gate spacer layer may be a single layer or a multi-layer. The at least one layer in the gate spacer layer may include silicon carbonitride, silicon oxycarbide, silicon oxycarbonitride, or silicon nitride. The gate spacer layer may be deposited over the dummy gate stack 220 using processes such as, a CVD process, a subatmospheric CVD (SACVD) process, an ALD process, or other suitable process. Subsequently, an anisotropic etching process may be implemented to remove portions of the gate spacer layer from top-facing surfaces of the semiconductor device 200, including from top-surfaces of the dummy gate stacks 220. The remaining portions of the gate spacer layer covers sidewalls of the dummy gate stacks 220 as the gate spacers 226.

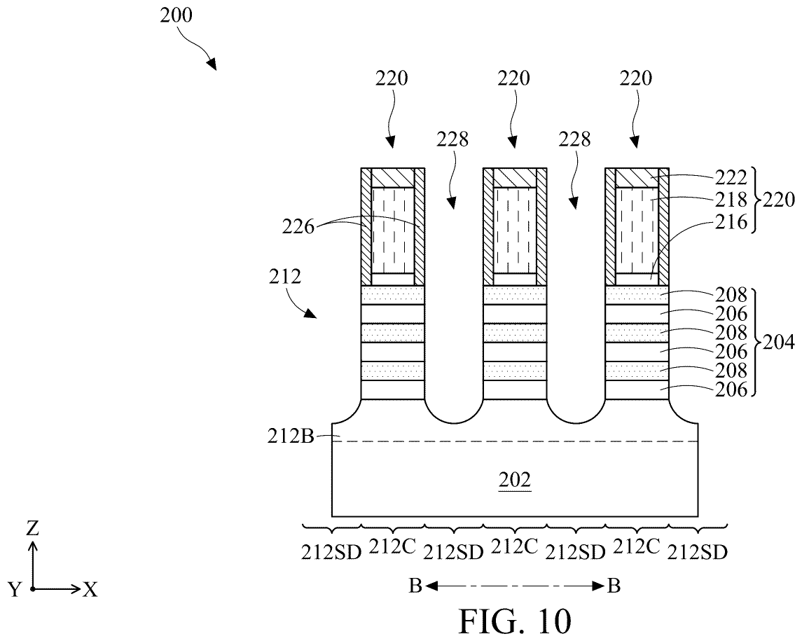

Referring to FIGS. 1 and 10, method 100 includes a block 112 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 110 may implement an oxygen-containing gas, a fluorine-containing gas (e.g., CF₄, SF₆, CH₂F₂, CHF₃, and/or C₂F6), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 10, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

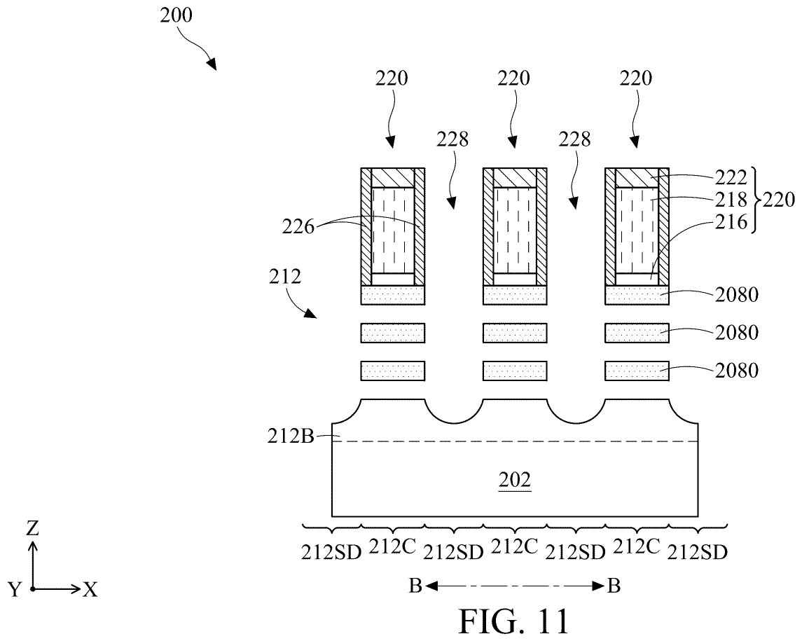

Referring to FIGS. 1 and 11, method 100 includes a block 114 where the plurality of channel layers 208 in the channel regions are released as channel members 2080. After the formation of the source/drain trenches 228, the sacrificial layers 206 interleaving the channel layers 208 in the channel region 212C are selectively removed. The selective removal of the sacrificial layers 206 releases the channel layers 208 to form the channel members 2080. Depending on the design, the channel members 2080 may take form of nanowires, nanorods, nanosheets, or other nanostructures. The selective removal of the sacrificial layers 206 forms spaces between and around adjacent channel members 2080. The selective removal of the sacrificial layers 206 may be implemented by a selective dry etching process. An example selective dry etching process may include use of one or more fluorine-containing (F-containing) gas. In some embodiments, the fluorine-containing gas can include fluorine (F₂), hydrogen fluoride (HF), chlorine trifluoride (ClF₃), fluorine radical (F*), and nitrogen trifluoride radical (NF₃*). The germanium concentration difference between the sacrificial layers 206 and the channel layers 208 provide proper etching selectivity. In some embodiments, the sacrificial layers 206 can be etched by a gas phase etching using fluorine-containing gases, such as F₂, HF, and ClF₃. In some embodiments, the sacrificial layers 206 can be etched by a radical phase etching using radicals, such as F*, H*, and NF₃*, generated from fluorine-containing gases by a remote plasma system. The dry etching process can have by-products, such as silicon tetrafluoride (SiF₄) and germanium tetrafluoride (GeF₄).

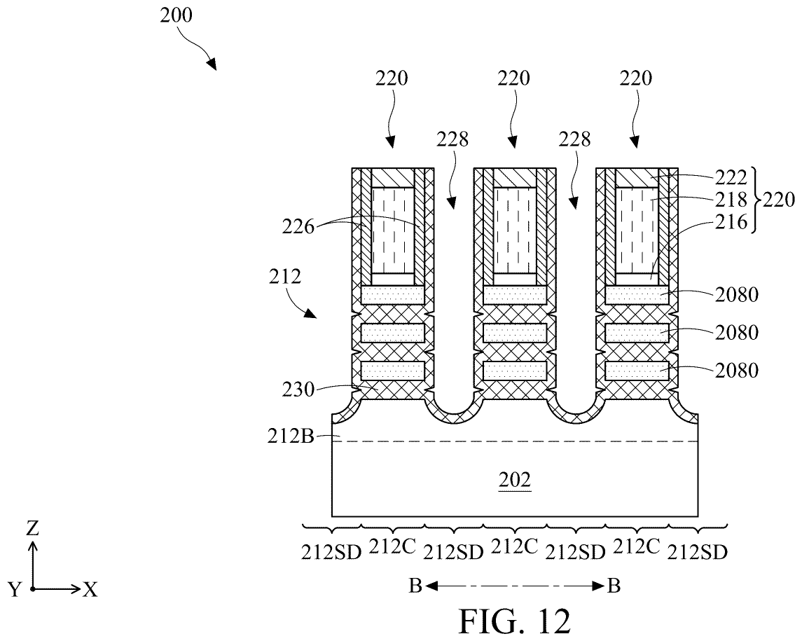

Referring to FIGS. 1 and 12, method 100 includes a block 116 where a dielectric dummy layer 230 is deposited around the channel members 2080 and over the source/drain trenches 228. The dielectric dummy layer 230 may be an oxide, such as silicon oxide in some embodiments, and may be deposited using ALD, flowable chemical vapor deposition (FCVD), plasma enhanced chemical vapor deposition (PECVD), or other suitable deposition processes. The dielectric dummy layer 230 fills the space among the channel members 2080 and covers sidewalls of the channel members 2080. In the illustrated embodiment, in order to improve the gap fill capability without leaving voids thereunder, the deposition of the dielectric dummy layer 230 may include an ALD process to first form a thin dielectric layer and a subsequent FCVD process to form a thick dielectric layer over the thin dielectric layer. The combination of the ALD and FCVD processes improves gap fill capability without compromising production throughput.

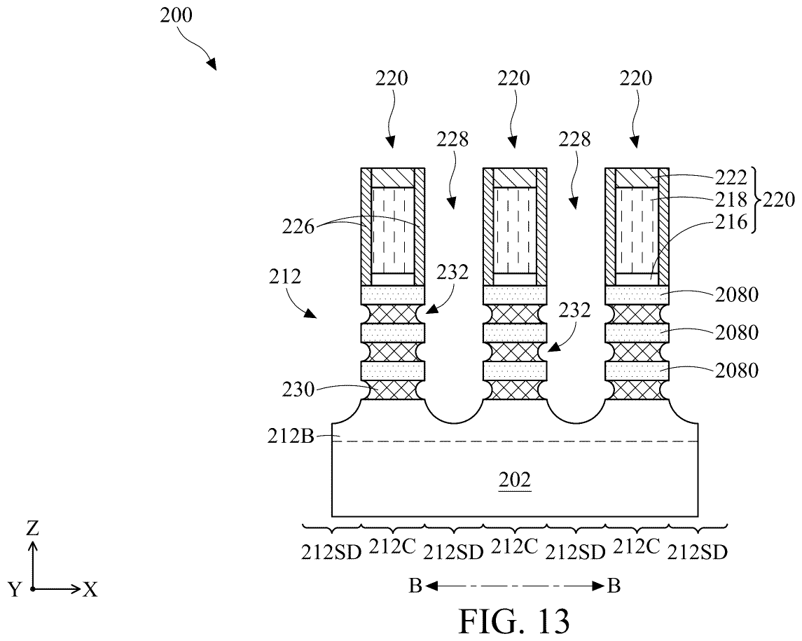

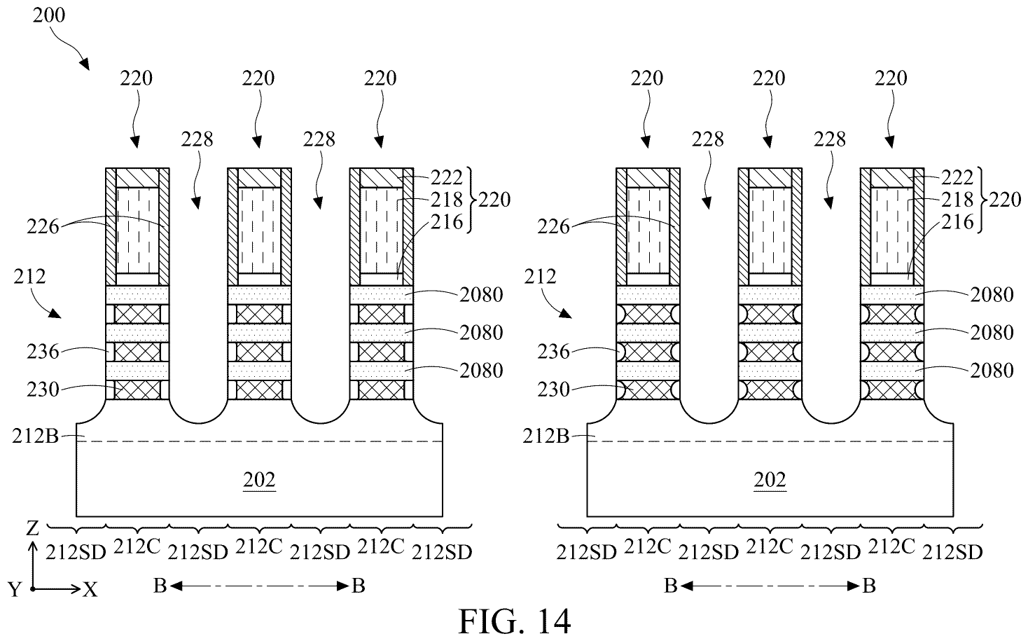

Referring to FIGS. 1 and 13, method 100 includes a block 118 where inner spacer recesses 232 are formed. The dielectric dummy layer 230 is selectively and partially recessed to form inner spacer recesses 232. The inner spacer recesses 232 may have a concave profile bending away from the source/drain trenches 228. Alternatively, the inner spacer recesses 232 may have a square profile (not separately shown in FIG. 13, but illustrated in the left-side figure in FIG. 14 after inner spacers are formed therein). In an embodiment, the selective recess of the dielectric dummy layer 230 may be performed using a selective wet etching process or a selective dry etching process. An example selective wet etching process may include use of diluted hydrofluoric acid (DHF) or a mixture of hydrofluoric acid (HF) and, ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As shown in FIG. 13, the dielectric dummy layer 230 is removed from the source/drain regions 212SD, and the fin-shaped base 212B is exposed.

Referring to FIGS. 1 and 14, method 100 includes a block 120 where inner spacers 236 are formed in the inner spacer recesses 232. The left-side figure in FIG. 14 corresponds to the inner spacer profile in a square-shape inner spacer recess, and the right-side figure in FIG. 14 corresponds to the inner spacer profile in a concave-shape inner spacer recess. The formation of the inner spacers 236 may include the deposition of an inner spacer layer over exposed surfaces of the source/drain trenches 228, including filling the inner spacer recesses 232. A composition of the inner spacer layer is different from a composition of the dielectric dummy layer 230 to ensure that each one of them may be selectively etched without substantially damaging the other one. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. Subsequently, the inner spacer layer is etched back to form inner spacers 236 in the inner spacer recesses 232. In some embodiments, the etching back of the inner spacer layer may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 236 substantially remain under the gate spacers 226 without extending to a position directly under the dummy gate stack 220. Alternatively, the inner spacers 236 may laterally extend to a position directly under the dummy gate stack 220. In the following figures, for the sake of simplicity, the manufacturing operations after the inner spacers 236 formed in concave-shape inner spacer recesses (structure shown in the right-side figure in FIG. 14) are explained. However, the same operations can be applied to the structure shown in the left-side figure in FIG. 14.

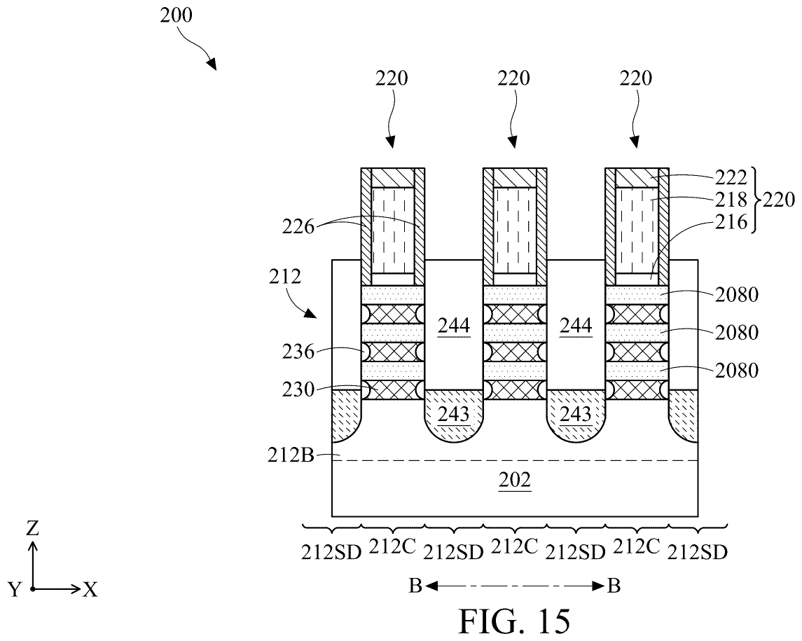

Referring to FIGS. 1 and 15, method 100 includes a block 122 where source/drain features 244 are epitaxially grown from the exposed semiconductor surfaces in the source/drain trenches 228, including from the sidewalls of the channel members 2080. While not explicitly shown, before any of the epitaxial layers are formed, method 100 may include a cleaning process to clean surfaces of the semiconductor device 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, a sulfuric peroxide mixture, and/or hydrofluoric acid for oxide removal. The dry clean process may include helium (He) and hydrogen (H₂) treatment.

The source/drain features 244 may be n-type or p-type. When the source/drain feature 244 is n-type, the source/drain feature 244 may include silicon (Si) and an n-type dopant, such as phosphorus (P), arsenic (As), antimony (Sb), or a combination thereof. When the source/drain feature 244 is p-type, the source/drain feature 244 may include silicon germanium (SiGe) and a p-type dopant, such as boron (B), boron difluoride (BF₂), or a combination thereof. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping. In the depicted embodiment, a bottom buffer layer 243 is formed under the source/drain feature 244 and in contact with a sidewall of the bottommost one of the inner spacer 236. The bottom buffer layer 243 suppresses leakage current from the source/drain region 212SD into the substrate 202. The bottom buffer layer 243 may be a dielectric layer, such as an oxide layer or a nitride layer. Alternatively, the bottom buffer layer 243 may be an epitaxial layer that is dopant free. When the source/drain feature 244 is n-type, the bottom buffer layer 243 may include undoped silicon (Si) or undoped silicon germanium (SiGe) and the source/drain feature 244 may include silicon (Si) and an n-type dopant, such as phosphorus (P), arsenic (As), antimony (Sb), or a combination thereof. When the source/drain feature 244 is p-type, the bottom buffer layer 243 may include undoped silicon (Si) or undoped silicon germanium (SiGe) and the source/drain feature 244 may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom buffer layer 243 may include a counter dopant to reduce leakage into the bulk substrate 202. For example, the bottom buffer layer 243 under the n-type source/drain feature 244 may include a p-type dopant, such as boron (B). For another example, the bottom buffer layer 243 under the p-type source/drain feature 244 may include an n-type dopant, such as phosphorus (P), arsenic (As), or antimony (Sb).

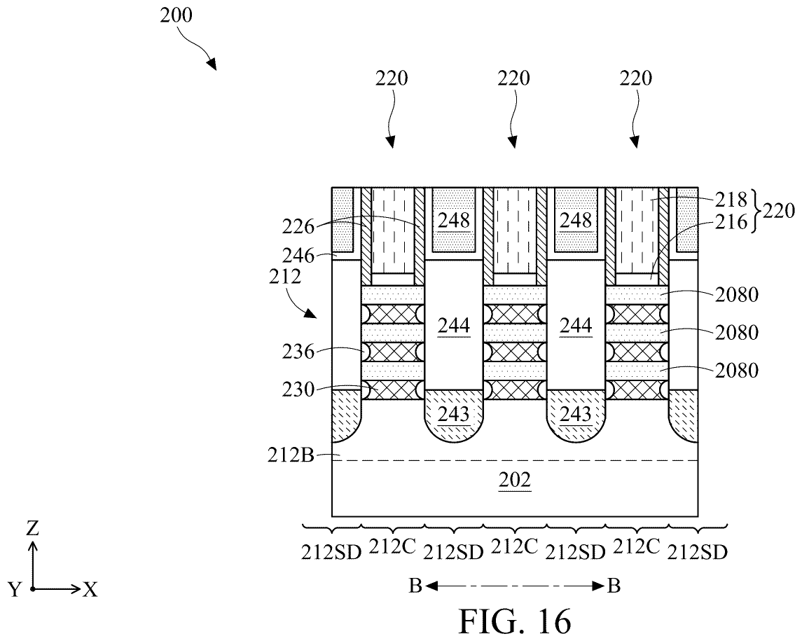

Referring to FIGS. 1 and 16-17, method 100 includes a block 124 where a contact etch stop layer (CESL) 246, an interlayer dielectric (ILD) layer 248, and a capping layer 249 are deposited in the source/drain regions 212SD. As shown in FIG. 16, the CESL 246 is deposited over the source/drain feature 244. The CESL 246 may include silicon nitride or aluminum nitride. In some implementations, the CESL 246 may be deposited using CVD or ALD. The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process.

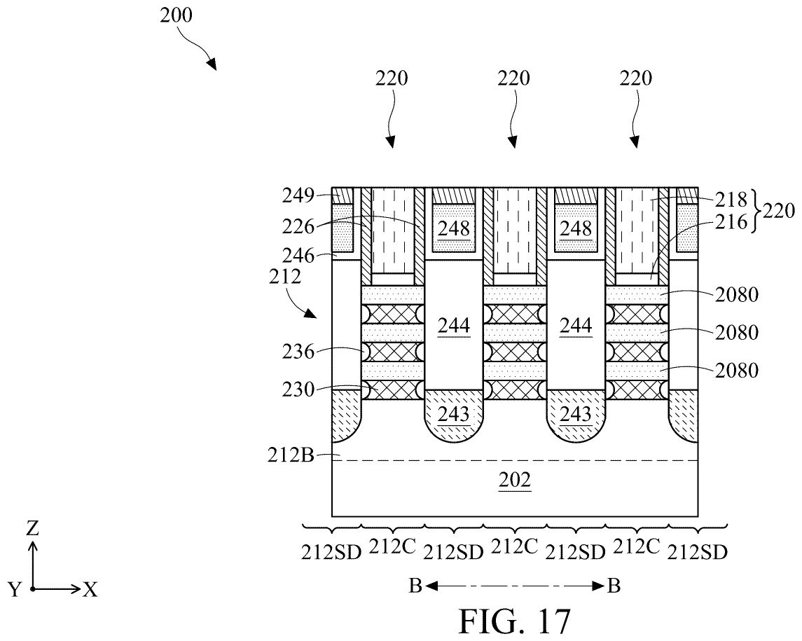

As shown in FIG. 17, in order to protect the ILD layer 248 from being damaged during the dielectric dummy layer 230 removal step, the ILD layer 248 is selectively recessed to form a top recess and a capping layer 249 is formed over the top recess. The capping layer 249 is formed of a different material than the dielectric dummy layer 230. When the dielectric dummy layer 230 includes silicon oxide, the capping layer 249 is not formed of silicon oxide so as to ensure etching selectivity. In some embodiments, the capping layer 249 may include silicon nitride, silicon carbonitride, silicon carbide, or silicon oxycarbonitride. In one embodiment, the capping layer 249 may include silicon nitride. Another planarization is performed to remove excess capping layer 249 and to expose the dummy gate stack 220. After the planarization, top surfaces of the capping layer 249, the CESL 246, the gate spacers 226, and the dummy gate stacks 220 are coplanar.

Referring to FIGS. 1 and 18-20, method 100 includes a block 126 where a hard mask layer 250 is formed over the dummy gate stack 220 and the capping layer 249 and an etching mask 252 is formed over the hard mask layer 250. The hard mask layer 250 may be a single-layer hard mask formed of, such as silicon nitride, silicon oxynitride, or the like, using a suitable formation method such as CVD. In some embodiments, the hard mask layer 250 has a multi-layered structure. For example, the hard mask layers 250 may include a silicon layer sandwiched between two silicon nitride layers. The etching mask 252 may have a single-layered structure (which may include a photoresist layer), or a dual-layered structure including a Bottom Anti-reflective Coating (BARC) layer and a photoresist layer. In the depicted embodiment, the etching mask 252 has a tri-layered structure, which includes a bottom layer 254 (e.g., a BARC layer), a middle layer 256 (e.g., a silicon nitride layer, or a silicon oxynitride layer), and a top layer 258 (e.g., a photoresist layer). Operations at block 126 also include forming an opening 260 in the top layer 258 of the etching mask 252. Next, the pattern of the top layer 258 is extended through the middle layer 256 and the bottom layer 254, and is transferred to the hard mask layer 250, using a suitable method, such as one or more anisotropic etching processes. Next, the etching mask 252 is removed by a suitable process, such as etching, ashing, combinations thereof, or the like.

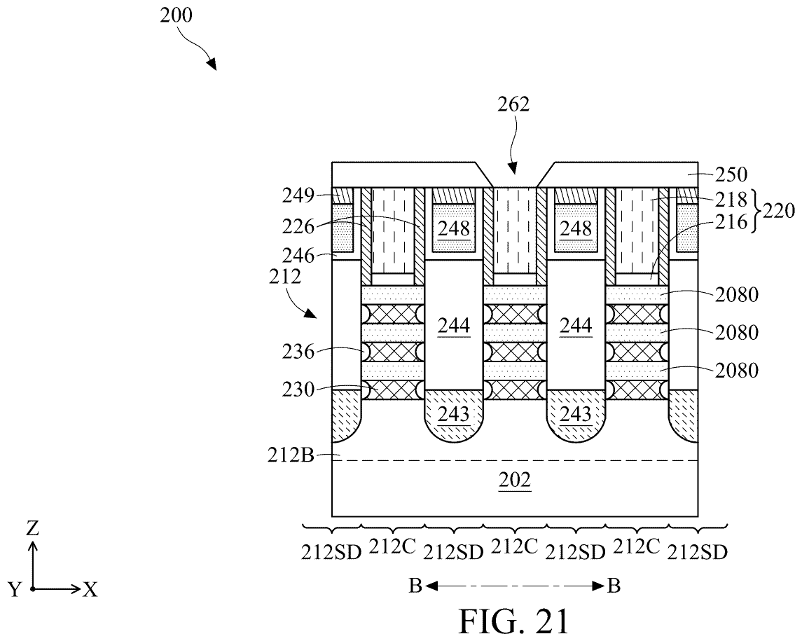

FIGS. 21-23 illustrate the semiconductor device 200 after the removal of the etching mask 252. The opening 260 is transferred to the hard mask layer 250 as an opening 262 in the hard mask layer 250. The opening 262 exposes a segment of the dummy gate stack 220, so that the exposed segment can be removed and replaced by an isolation structure in subsequent processing. The removal of the dummy gate stack 220 is also referred to as a CPODE process, the trench formed thereafter is also referred to as a CPODE trench, and the isolation structure filling the CPODE trench is also referred to as a CPODE feature, details of which are discussed hereinafter.

Referring to FIGS. 1 and 24-26, method 100 includes a block 128 where a first etching process, such as a highly selective (e.g., Si over SiO and/or SiN) dry etching process, is performed to remove an upper portion of the exposed segment of the dummy gate stack 220. The gate spacers 226 substantially remain intact during the first etching process and limits the first etching process between the opposing sidewalls of the gate spacers 226 in the X-Z plane. The first etching process may be controlled (e.g., timed), such that after the first etching process, the dummy dielectric layer 216 disposed on the top surface of the fin-shaped structures 212 is exposed. Alternatively, the first etching process may also remove the portion of the dummy dielectric layer 216 disposed on the top surface of the fin-shaped structure 212 and expose the topmost one of the channel members 2080. An example dry etching process may include use of anhydrous hydrogen fluoride (HF) vapor, trifluoromethane (CHF₃), CH₂F₂, CH₃F, HBR, Cl₂, nitrogen trifluoride (NF₃), hydrogen (H₂), ammonia (NH₃), carbon tetrafluoride (CF₄), sulfur hexafluoride (SF₆), or a combination thereof. To reduce the damage risk for source/drain features and ILD features, the dry etching process may be controlled in a way such that the lower portion of the dummy gate stack 220 and/or the dummy dielectric layer 216 are kept.

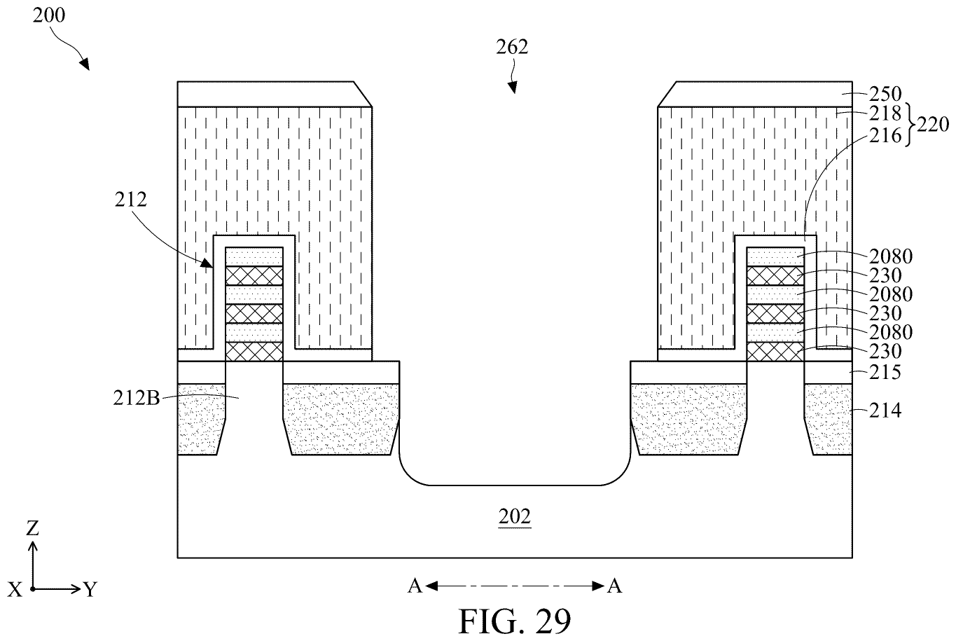

Referring to FIGS. 1 and 27-29, method 100 includes a block 130 where a second etching process, such as an anisotropic etching process, is performed to remove the fin-shaped structure(s) in the opening 262. Notably, the second etching process has a low etching selectivity between the semiconductor material (e.g., Si) of the channel members 2080 and the oxide material (e.g., silicon oxide) of the dielectric dummy layer 230, such that the channel members 2080 and the dielectric dummy layer 230 are removed together during the second etching process. In some embodiments, a ratio of the etching rate of the channel members 2080 and the etching rate of the dielectric dummy layer 230 ranges from about 1:3 to about 3:1. Due to the low etching selectivity, the second etching process also etches through the fin-shaped bases 212B and the isolation feature 214 between the fin-shaped bases 212B. As a result, the bottom surface of the opening 262 is extended to below the bottom surface of the isolation feature 214. The opening 262 is also referred to as the CPODE trench 262. Due to the low selectivity etching, majority of the bottom surface of the CPODE trench 262 is substantially flat in the Y-Z plane, as illustrated in FIG. 29. In a perfect none-selective process, the etch front is flat. However, the etch front will not be flat if the process still has some etch selectivity. For example, if oxide was etched faster than Si, deeper recess will be found on the STI site, and vice versa. The etch selectivity can be controlled by tuning the etchant composition, pressure, and bias power in the processes. In generally higher BCl₃ concentration usually leads to faster oxide etch rates. Lower pressure and larger bias power usually leads to lower etch selectivity. Also as depicted in FIG. 29, in the Y-Z plane the CPODE trench 262 has an upper portion above the top surface of the hard mask layer 215 that is wider than a lower portion below the top surface of the hard mask layer 215.

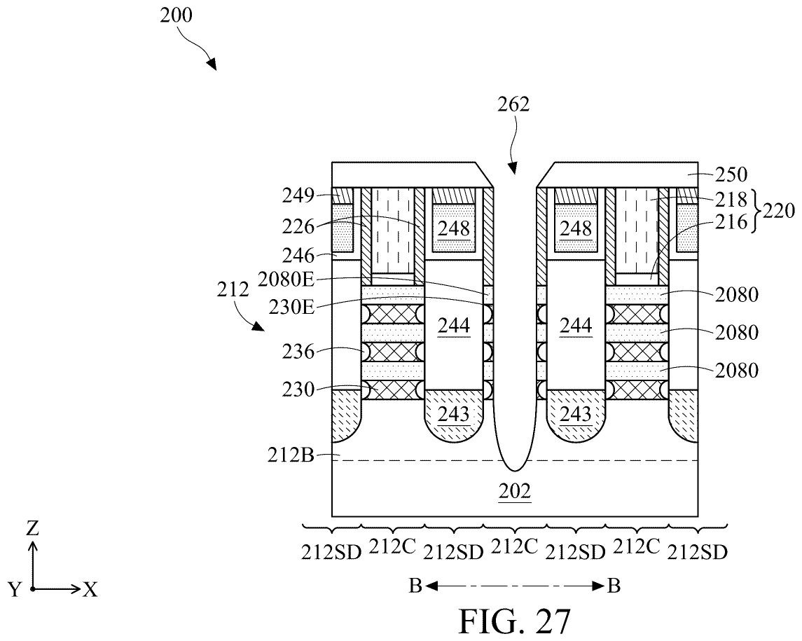

Notably, as depicted in FIG. 27, due to the high directivity of the anisotropic etching, the gate spacers 226 may protect a portion of the fin-shaped structure 212 directly under the gate spacers 226 from removing. The remaining portion of the fin-shaped structure 212 may include end portions of the channel members 2080 (denoted as semiconductor ends 2080E thereafter), end portions of the dielectric dummy layer 230 (denoted as dielectric ends 230E thereafter, particularly at the edges of the inner spacers when the inner spacers have a convex profile), and the inner spacers 236. If the inner spacers 236 do not laterally extend beyond sidewalls of the gate spacers 226, the inner spacers 236 remain as a whole, and the dielectric ends 230E cover the inner spacers 236 from exposing in the CPODE trench 262; if the inner spacers 236 laterally extend beyond sidewalls of the gate spacers 226, the inner spacers 236 and the dielectric ends 230E are both exposed in the CPODE trench 262. In some embodiments, the semiconductor ends 2080E include silicon, the dielectric ends 230E include silicon oxide, and the inner spacers 236 include silicon nitride.

In some embodiments, the anisotropic etching process is a plasma dry etching process. The plasma dry etching process may be performed using a gas source comprising HBr and BCl₃. The low etching selectivity can be achieved by adjusting the ratio of HBr/BCl₃. Higher the ratio of HBr/BCl₃ leads to a higher etching rate for Si but a lower etching rate for silicon oxide, and vice versa. The ratio of may range HBr/BCl₃ from about 0 to about 100. Other gases, such as Cl₂, may be added to increase the etching rates for both Si and silicon oxide. In some embodiments, during the plasma dry etching process, other gases, such as O₂, CO₂, or a combination thereof, may be added to the gas source to adjust various aspects of the plasma dry etching process, such as etching rate, etching selectivity, and/or etching profile.

During the plasma dry etching process, the gas source is ignited into plasma by a plasma etching tool. The plasma etching tools may use an Inductively Coupled Plasma (ICP)/dipole antenna. In some embodiments, an RF power generator of the plasma etching tool generates an RF power source (e.g., an RF signal) at 13.56 MHz or 27 MHz. The plasma etching tool chamber may be operated at a pressure between about 3 mTorr and about 150 mTorr, and at a temperature between about 20 degrees Celsius and about 200 degrees Celsius. A power of the RF power source may be between about 100 W and about 2500 W. In some embodiments, the plasma dry etching process uses pulsed plasma etch, where a duty cycle of the RF power source is in a range between about 5% to 100%. In some embodiments, an RF bias power to the pedestal of the plasma etching tool between about 10 W and about 1200 W is used for the plasma dry etching process.

In some embodiments, in order to protect the hard mask layer 250 and to preserve the dimension of the CPODE trench 262 during the plasma dry etching process, a passivation layer is formed (e.g., conformally) over the upper surface of the hard mask layer 250 and along the sidewalls and the bottom of the CPODE trench 262. The passivation layer may be a carbon-based passivation layer formed by injecting CH₄ into the plasma etching tool during the plasma dry etching process. A carrier gas, such as Ar or N₂, may be used to carrier CH₄ into the plasma etching tool. In some embodiments, the passivation layer is a SiO-based passivation layer formed by injecting SiCl₄ and O₂ gases (e.g., simultaneously or sequentially) into the plasma etching tool during the plasma dry etching process. A carrier gas, such as Ar or N₂, may be used to carrier SiCl₄ and O₂ into the plasma etching tool. The SiO-based passivation layer may be formed by the chemical reaction:

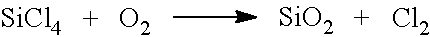

In some embodiments, addition chemical(s), such as HBr, is injected into the plasma etching tool chamber along with SiCl₄ to facilitate the dissociation of SiCl₄ in the SiO-based passivation layer formation process. Chemical reactions, such as

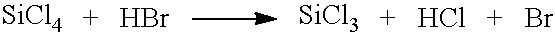 [SMILES: "SiCl4" ; Br ; "SiCl3" ; Cl ; Br]

may happen to speed up the dissociation of SiCl₄ and the formation of SiO-based passivation layer. The bromine (Br) generated by the above chemical reaction may further react with SiO₂ to form SiBrO. Therefore, the composition of the SiO-based passivation layer may include SiBrO.

After the passivation layer is formed, a break-through etching step is performed to remove the passivation layer from the etch front (e.g., remove the passivation layer from the bottom of the CPODE trench 262), such that the plasma dry etching process can be performed next to extend the CPODE trench 262. In some embodiments, the break-through etching step is an anisotropic etching process (e.g., a plasma etching process) performed using a gas source comprising CF₄, CHF₃, C₄F₆, or combinations thereof. After the break-through etching step, the passivation layer at the bottom of the CPODE trench 262 is removed, while the sidewalls of the CPODE trench 262 remain covered by the passivation layer.

In some embodiments, the second etching process includes multiple etching cycles, where each of the multiple etching cycles includes the following three sequential processing steps: 1) forming the passivation layer (e.g., carbon-based or SiO-based passivation layer) on the hard mask layer 250 and along the sidewalls and the bottom of the CPODE trench 262; 2) performing the break-through etching step to remove the passivation layer from the etch front; and 3) performing the plasma dry etching process to remove the fin-shaped structure(s) 212 and further extend the CPODE trench 262. In some embodiments, the passivation layer remains on sidewalls of the CPODE trench 262 after the second etching process. In some alternative embodiments, the passivation layer is fully removed from the CPODE trench 262 after the second etching process.

Referring to FIGS. 1 and 30-32, method 100 includes a block 132 where an isolation structure 270 is formed in the CPODE trench 262. The isolation structure 270 is also referred to as the CPODE feature 270. The CPODE feature 270 may be a single layer structure or a multi-layer structure. For a multi-layer structure, a dielectric liner 272 may be conformally deposited on the sidewalls and the bottom surface of the CPODE trench 262, such as by an ALD process. In some embodiments, the dielectric liner 272 is an oxide (e.g., silicon oxide). Subsequently, a dielectric layer 274 is deposited in the CPODE trench 262. The dielectric layer 274 fills up the CPODE trench 262. In some embodiments, the dielectric layer 274 is free of oxygen, such as a nitride (e.g., silicon nitride or silicon carbonitride). The dielectric layer 274 may be deposited by ALD, CVD, PVD, or other suitable processes. The dielectric liner 272 and the dielectric layer 274 collectively define the CPODE feature 270. At the conclusion of block 132, a planarization process (e.g., CMP) may be performed to remove excess portions of the dielectric liner 272, the dielectric layer 274, and the hard mask layer 250 to expose other dummy gate stacks 220.

Referring to FIGS. 1 and 33-34, method 100 includes a block 134 where the dummy gate stacks 220 are selectively removed. Exposure of the dummy gate stack 220 allows the removal thereof. The removal of the dummy gate stack 220 may include one or more etching processes that are selective to the materials of the dummy gate stack 220. For example, the removal of the dummy gate stack 220 may be performed using a selective wet etch, a selective dry etch, or a combination thereof that is selective to the dummy gate stack 220. The removal of the dummy gate stack 220 exposes the sidewalls of the CPODE feature 270 and the stacks of the channel members 2080 and the dielectric dummy layer 230.

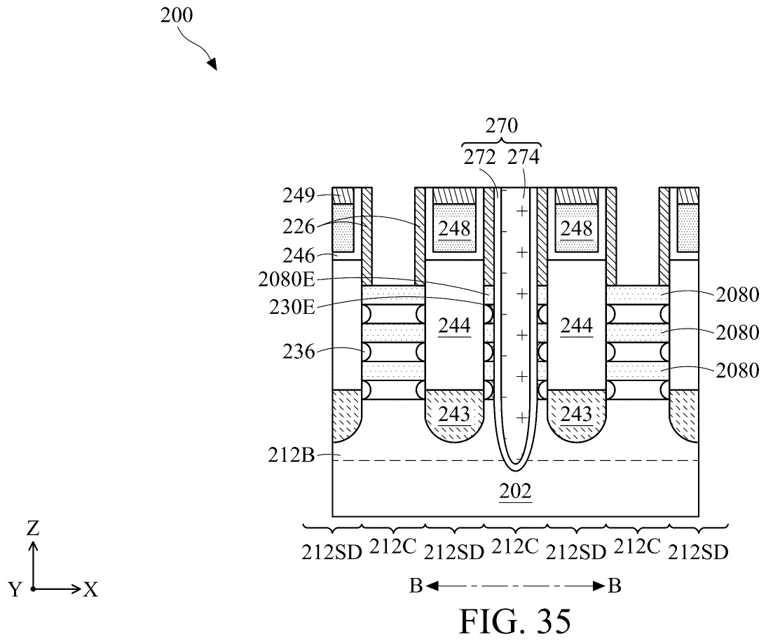

Referring to FIGS. 1 and 35-36, method 100 includes a block 136 where the dielectric dummy layer 230 is selectively removed from the channel regions 212C. After the removal of the dummy gate stack 220, the dielectric dummy layer 230 in the channel regions 212C is exposed and subsequently removed in a separate etching process. For example, a selective wet etching process or a selective dry etching process may be performed to remove the dielectric dummy layer 230. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. By design, the etch selectivity of the dielectric dummy layer 230 over the channel members 2080 may be larger than about 1000:1, such that the channel members 2080 remain substantially intact. After the selective removal of the dielectric dummy layer 230, the channel members 2080 in the channel regions 212C are once again exposed. Since the channel members 2080 are protected from the etching process by a high etching contrast, a surface roughness of the channel members 2080 after being exposed may be less than about 0.5 nm. Notably, as shown in FIG. 35, the dielectric ends 230E in contact with the CPODE feature 270 are not exposed to the etchants applied during the removal of the dielectric dummy layer 230 and remain in the semiconductor device 200.

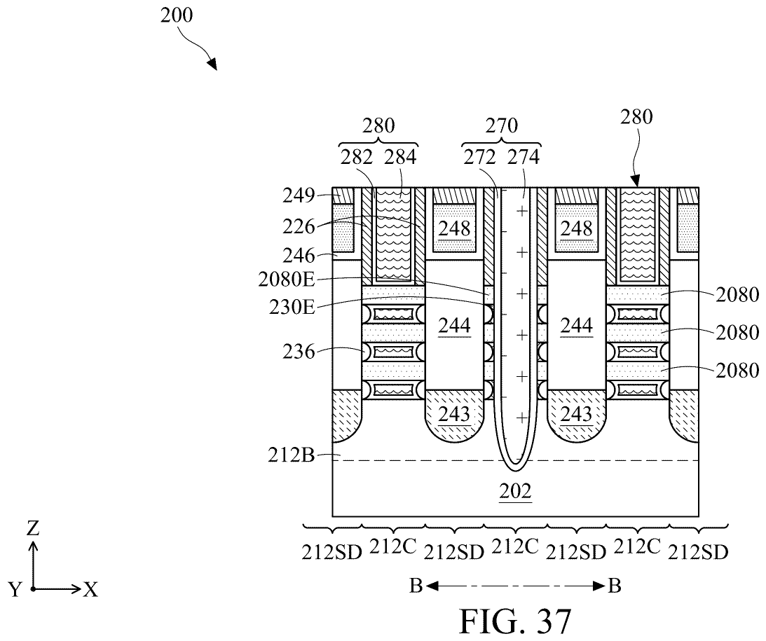

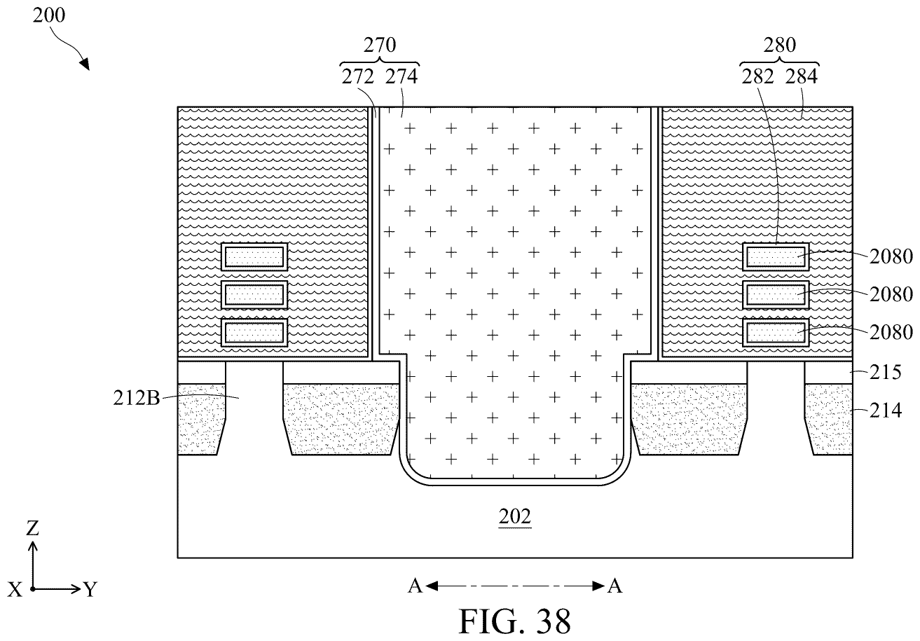

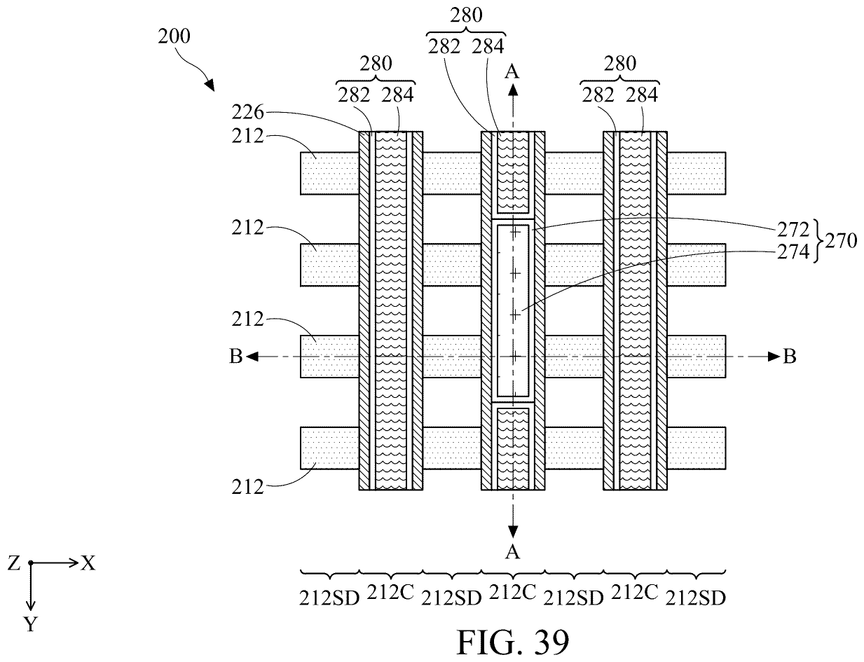

Referring to FIGS. 1 and 37-39, method 100 includes a block 138 where metal gate structure 280 is formed to wrap around each of the channel members 2080. FIG. 39 is a fragmentary top view of the semiconductor device 200 at the conclusion of block 138, FIG. 38 is a cross-sectional view along the A-A line in FIG. 39 (also the A-A line in FIG. 2), and FIG. 37 is a cross-sectional view along the B-B line in FIG. 39 (also the B-B line in FIG. 2). After the release of the channel members 2080, the metal gate structure 280 is formed to wrap around each of the channel members 2080. The gate structure 280 is also referred to as metal gate structure 280 due to its metal-containing layers. In the depicted embodiment, the gate structure 280 includes a gate dielectric layer 282 and a gate electrode layer 284 over the gate dielectric layer 282. Not explicitly shown, the gate dielectric layer 282 may further includes an interfacial layer interfacing the channel members 2080 and a high-k dielectric layer over the interfacial layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO4), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer may be formed by ALD, physical vapor deposition (PVD), CVD, oxidation, and/or other suitable methods.

The gate electrode layer 284 of the gate structure 280 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 284 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 284 may be formed by ALD, PVD, CVD, e-beam evaporation, or other suitable process. In various embodiments, a CMP process may be performed to remove excessive metal, thereby providing a substantially planar top surface of the gate structure. The gate structure 280 includes portions that interpose between channel members 2080 in the channel region 212C. In some embodiments, the gate structure 280 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

The portions of the gate structure 280 divided by the CPODE feature 270 may each be referred to as a gate structure individually. Notably, as shown in FIG. 38, the two portions of the gate structure 280 disposed on two opposing sides of the CPODE feature 270 may have opposite conductivity types, such as one being a p-type and another being an n-type. Correspondingly, the substrate 202 may be pre-doped with suitable dopants in forming an n-type well and a p-type well. The CPODE feature 270 may be disposed above a boundary between the n-type well and the p-type well. The CPODE feature 270 extends below the bottom surface of the isolation feature 214 and may help reducing leakage current in the substrate 202. In various embodiments, CPODE feature may also be applied to n-type well, p-type well, or the interface between n-type well and p-type well, regardless of transistor conductivity types.

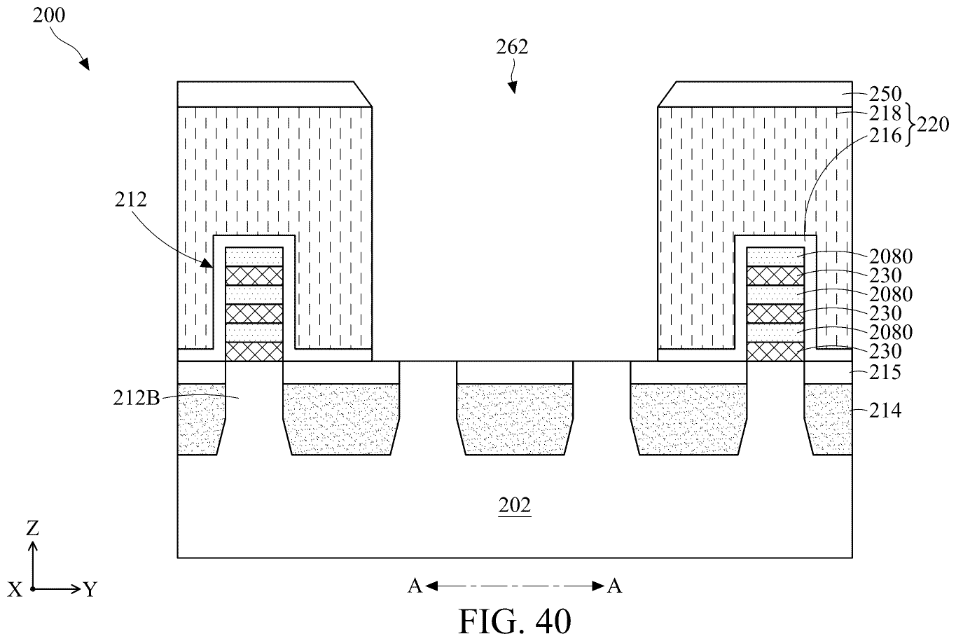

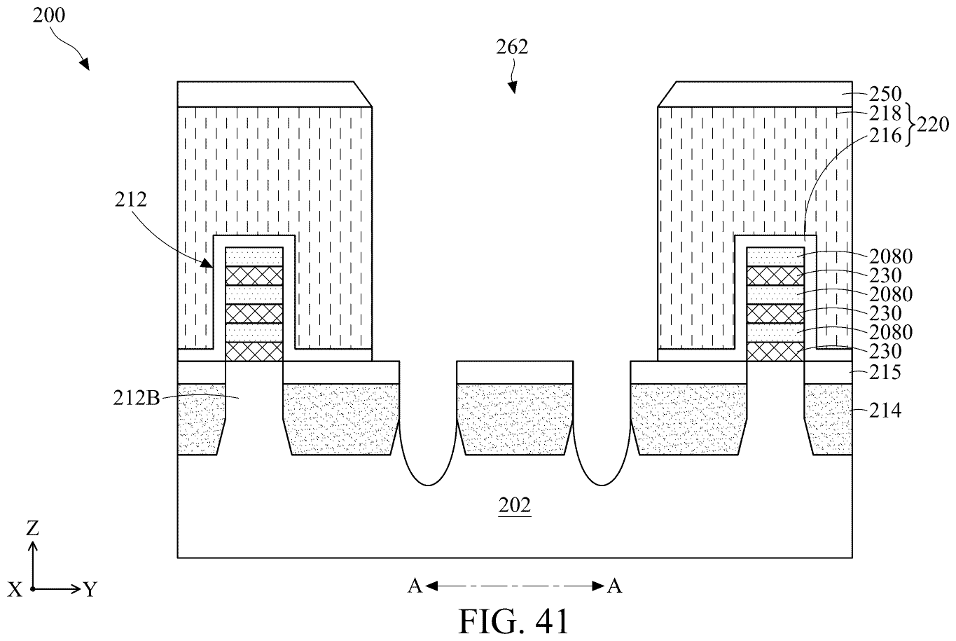

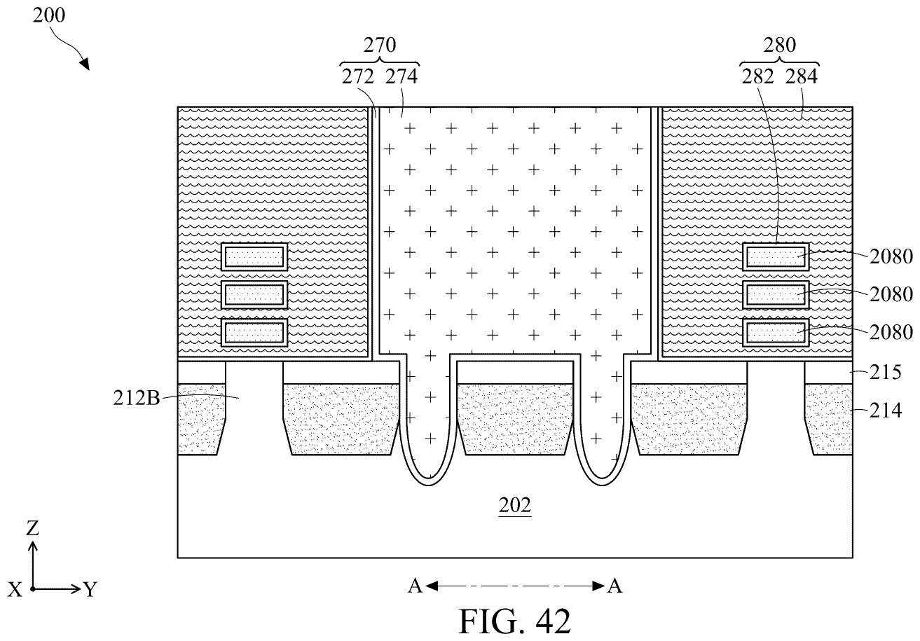

FIGS. 40-42 illustrate an alternative embodiment of method 100 and the resultant semiconductor device 200. Referring to FIGS. 40 and 41, the second etching process with a low etching selectivity performed at block 130 is switched to a third etching process with a high etching selectivity. In some embodiments, the third etching process is an anisotropic etching process, such as a plasma dry etching process, with an etching rate of a semiconductor material (e.g., Si) significantly higher than a dielectric material (e.g., silicon oxide). Moreover, the amount of STI consumed in the etching process can be controlled by process time of the second etching process and the selectivity of second and third processes. The third etching process may also include HBr and BCl₃, but with a much higher ratio of HBr/BCl₃ (e.g., >10) to boost the etching rate of the semiconductor material. In furtherance of the example, the etchant may be even free of BCl₃. As a result, the fin-shape bases 212B are removed, while the isolation feature 214 and the hard mask layer 215 laterally between the fin-shape bases 212B remain substantially intact. Accordingly, protrusions (or notches) occur at the bottom of the CPODE trench 262. After the CPODE trench 262 is filled with the CPODE feature 270, the CPODE feature 270 inherits the protrusions at its bottom, as shown in FIG. 42. The protrusions extend below the bottom surface of the isolation feature 214.

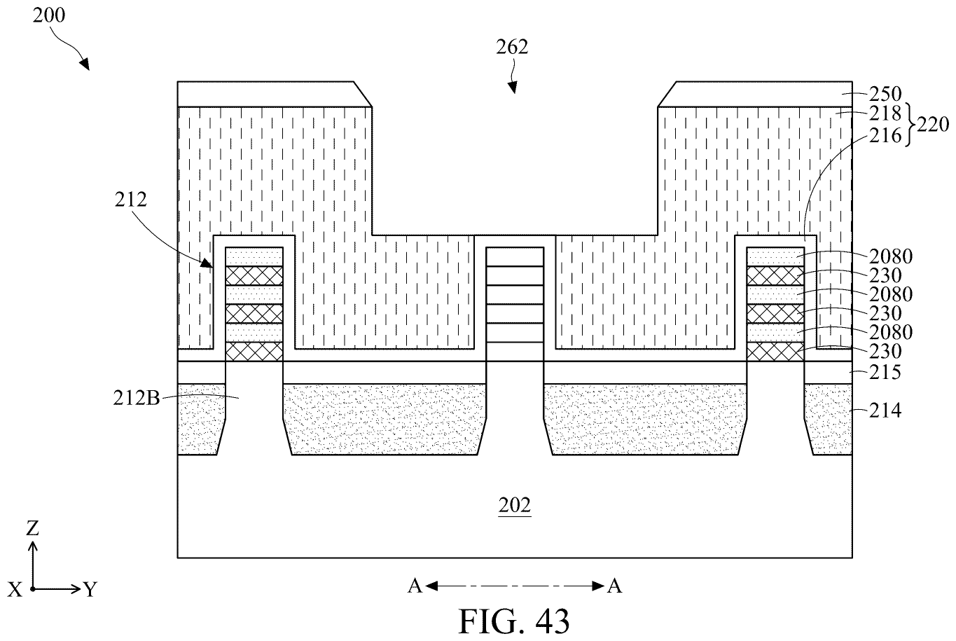

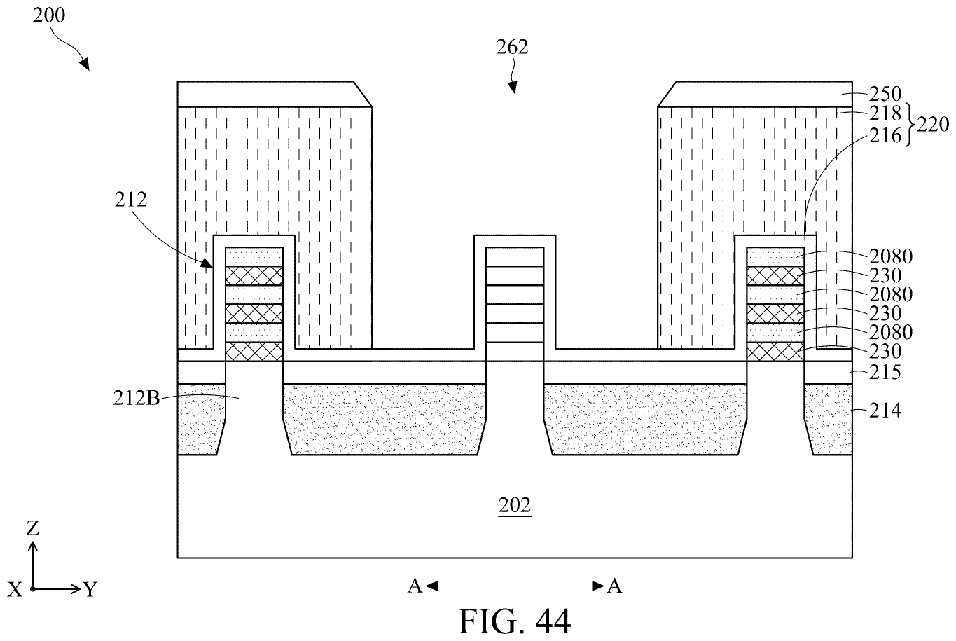

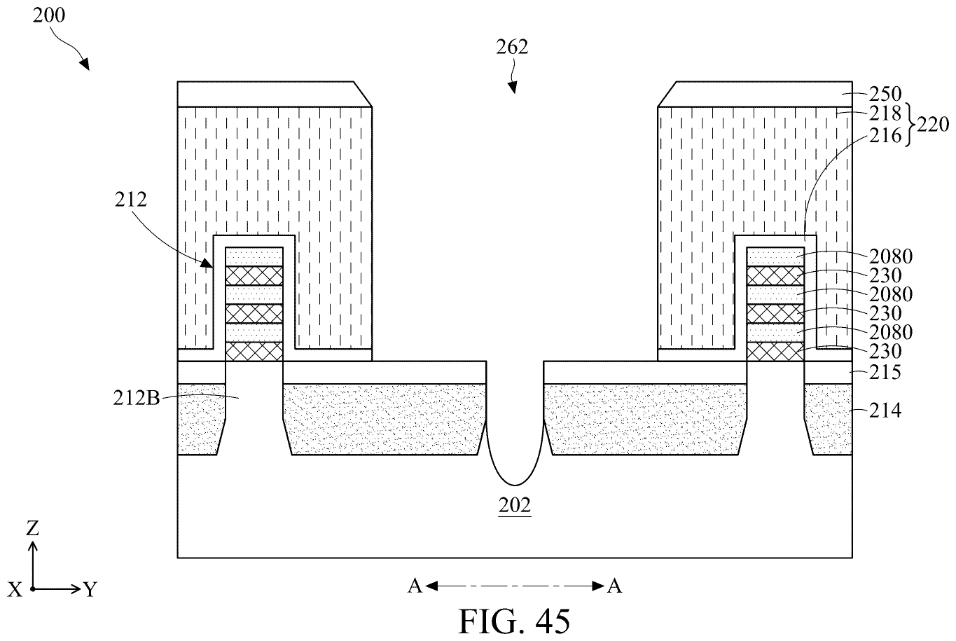

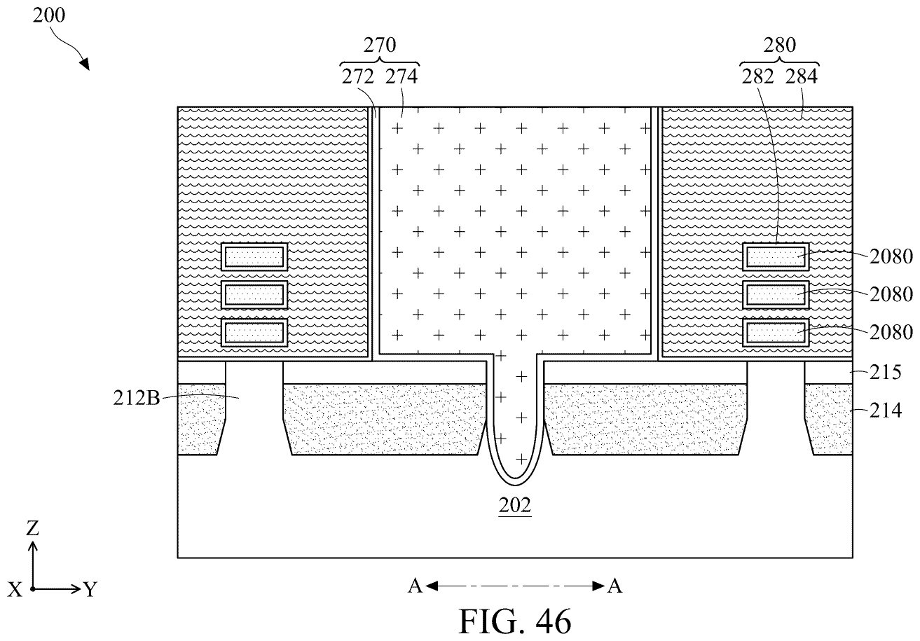

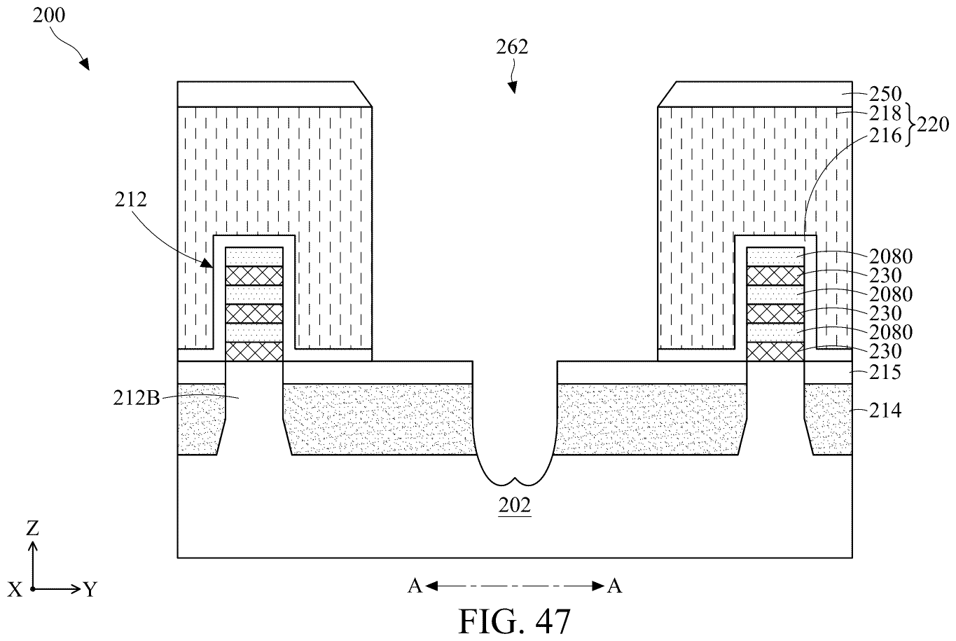

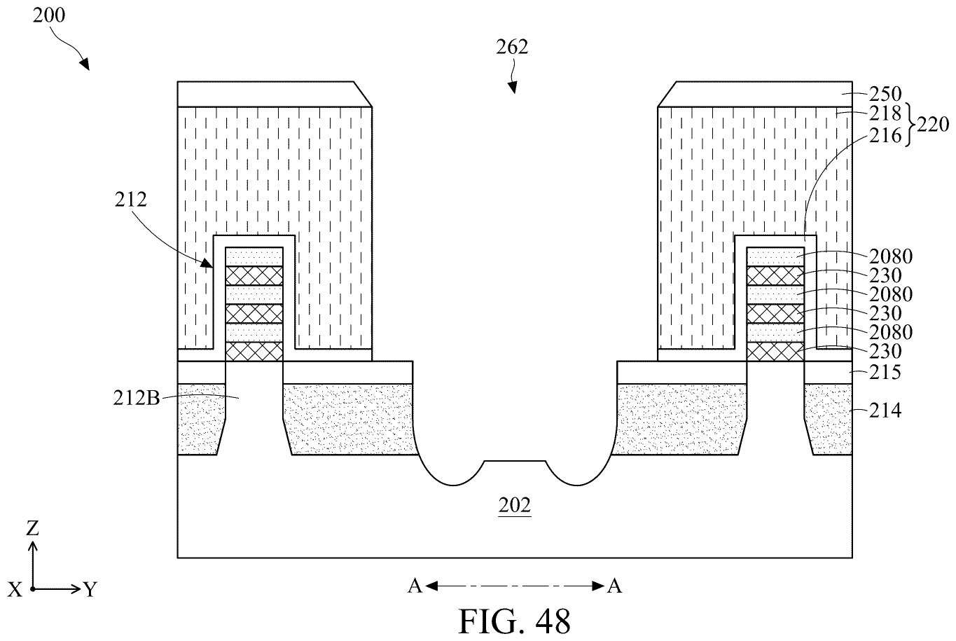

In the previous embodiments, two fin-shaped structures 212 are removed from the CPODE trench 262. This is, of course, a non-limiting example. The number of the fin-shaped structures 212 removed from the CPODE trenches 262 may be any suitable number. FIGS. 43-47 illustrates the scenario with a single fin-shaped structure 212 being removed from the CPODE trench 262. In FIG. 43, after the first etching process, a top portion of the dummy gate stack 220 is removed. In FIG. 44, the first etching process continues to remove the bottom portion of the dummy gate stack 220 until the dummy dielectric layer 216 disposed on the hard mask layer 215 is exposed. In FIG. 45, the second etching process with a low etching selectivity removes the channel members 2080 and the dielectric dummy layer 230 simultaneously, as well as the dummy dielectric layer 216. The second etching process also extends the CPODE trench 262 below the bottom surface of the isolation feature 214. In FIG. 46, the CPODE feature 270 is formed in the CPODE trench 262 with a protrusion at its bottom. Notably, in some embodiments, when the fin-shape structure 212 is narrow than about 30 nm (measured along the Y-direction), there is no separate notches at the bottom of the protrusion, as shown in FIGS. 45 and 46. If the fin-shape structure 212 is wider than 30 nm, two notches may appear. FIG. 47 shows the scenario when the fin-shape structure 212 has a width between about 30 nm and about 60 nm, in which two notches in proximity appear in the bottom of the CPODE trench 262. FIG. 48 shows the scenario when the fin-shape structure 212 has a width larger than about 60 nm, in which two separated notches appear in the bottom of the CPODE trench 262.

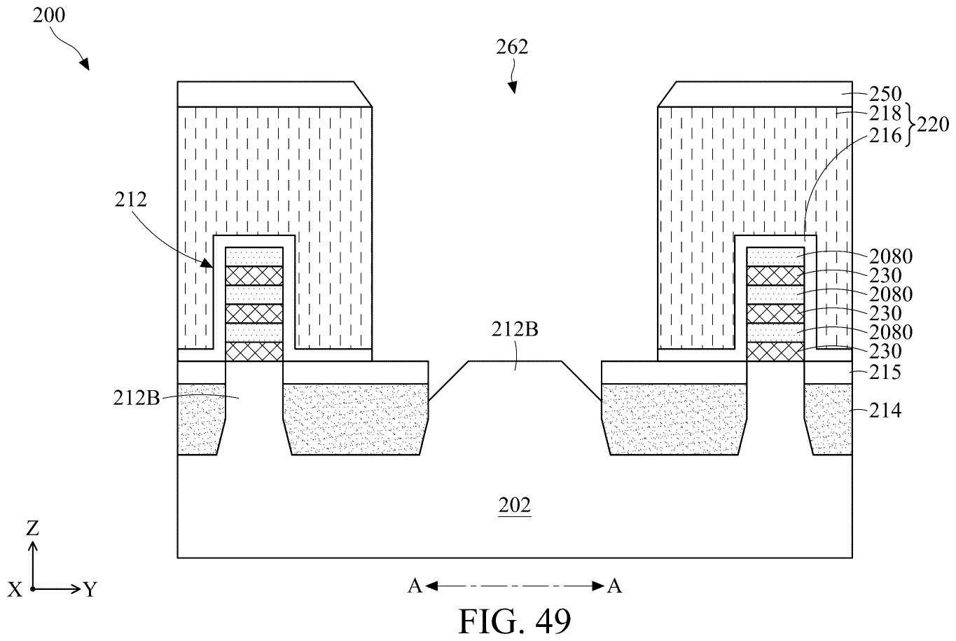

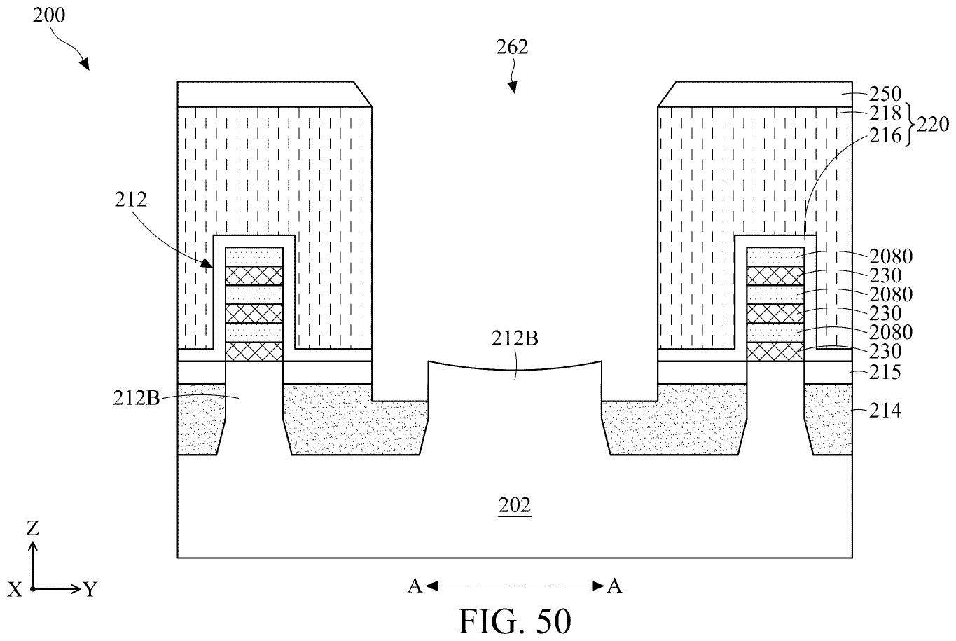

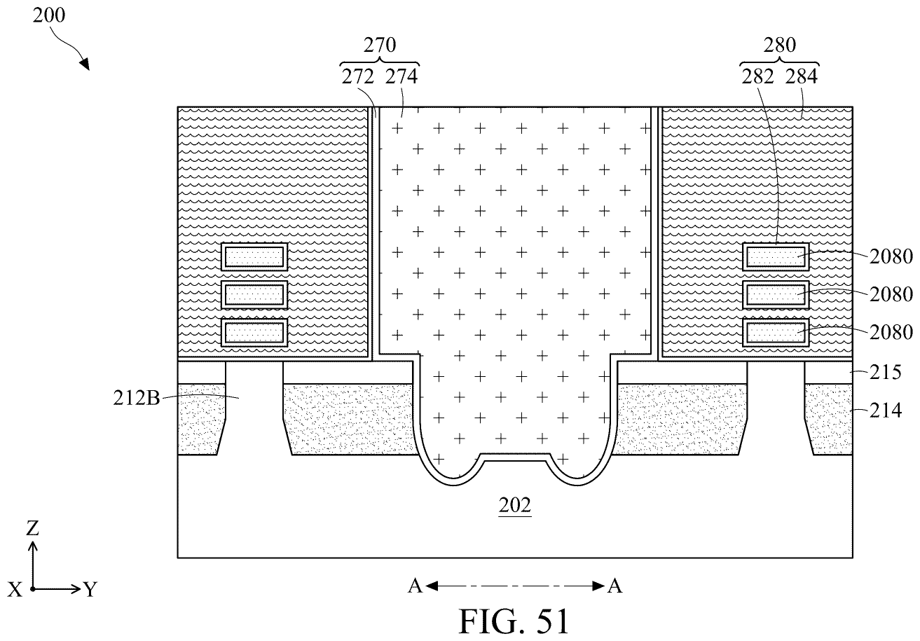

When the etching rates of the semiconductor material (e.g., Si) and the dielectric material (e.g., silicon oxide) are different, notches may also occur. FIG. 49 illustrates the scenario when the etching rate of Si is larger than the etching rate of silicon oxide, in which two notches starts to appear when the second etching process with a low etching selectivity arrives at the fin-shaped base 212B. These two notches will be extended to the bottom of the CPODE trench 262, as in FIG. 48. FIG. 50 illustrates another scenario when the etching rate of Si is smaller than the etching rate of silicon oxide, in which two notches starts to appear due to the faster recessing of the isolation feature 214. These two notches will be extended to the bottom of the CPODE trench 262, as in FIG. 48. FIG. 51 illustrates the resultant semiconductor device 200 after the metal gate structure 280 is formed. The bottom of the CPODE feature 270 may have two protrusions connected with a relatively flat portion.

Although not intended to be limiting, embodiments of the present disclosure provide one or more of the following advantages. For example, embodiments of the present disclosure replace germanium-containing sacrificial layers with oxide-containing dielectric dummy layers. During a replacement gate process, the dielectric dummy layers are selectively removed to release the channel members. A metal gate structure is then formed to wrap around each of the channel members. Such a process increases the etching contrast during the release of the channel members and improves the profile uniformity in the channel region of a GAA transistor. Further, an isolation structure is formed to separate different segments of the metal gate structure. The isolation structure is formed by filling a trench formed by removing the channel members and the dielectric dummy layers altogether in a directional low etching selectivity process. The low etching selectivity process prevents the dielectric dummy layers from forming dielectric residues remaining in spaces between the channel members. Still further, according to some of the exemplary approaches, Ge remaining in the CPODE trenches would substantially be free. Such approaches are especially suitable for the application with a need for high AC (low parasitic capacitance) and high current (wide nanosheet) performance. Compared to other methods utilizing isotropic etch to remove oxide interposer and anisotropic etch to remove nanosheet channels, such anisotropic and low selective etch approaches enable substantial inner spacer to remain and minimal impact to oxide. Moreover, the embodiments of the present disclosure can be readily integrated into existing semiconductor manufacturing processes.

In one exemplary aspect, the present disclosure is directed to a method. The method includes forming a stack that includes a plurality of channel layers interleaved by a plurality of sacrificial layers, patterning the stack to form a fin-shaped structure, forming an isolation feature on sidewalls of the fin-shaped structure, forming a dummy gate stack over a first region of the fin-shaped structure and a top surface of the isolation feature, depositing gate spacers on sidewalls of the dummy gate stack, after the depositing of the gate spacers, recessing a second region of the fin-shaped structure outside of the dummy gate stack and the gate spacers to form a first trench, selectively removing the sacrificial layers in the first region to release the channel layers as channel members, depositing dielectric dummy layers in spaces between adjacent two of the channel members, forming an epitaxial feature in the second region, forming a hard mask layer above the dummy gate stack, patterning the hard mask layer to form an opening directly above the first region of the fin-shaped structure, performing an etching process through the opening to remove the channel members and the dielectric dummy layers in the fin-shaped structure simultaneously, such that a second trench is formed through the dummy gate stack, and depositing an isolation structure in the second trench. The isolation structure divides the dummy gate stack into two segments. In some embodiments, the method further includes replacing the two segments of the dummy gate stack with two metal gate structures. In some embodiments, the performing of the etching process extends the second trench below a bottom surface of the isolation feature. In some embodiments, the method further includes after the performing of the etching process, performing another etching process different from the etching process to extend the second trench below a bottom surface of the isolation feature. In some embodiments, the method further includes prior to the performing of the etching process, recessing the dummy gate stack through the opening until a gate dielectric layer of the dummy gate stack is exposed. In some embodiments, the method further includes prior to the performing of the etching process, recessing the dummy gate stack through the opening until the fin-shaped structure is exposed. In some embodiments, the method further includes prior to the performing of the etching process, recessing the dummy gate stack through the opening until the isolation feature is exposed. In some embodiments, the forming of the isolation feature includes depositing a first dielectric layer on the sidewalls of the fin-shaped structure, and depositing a second dielectric layer above the first dielectric layer. The second dielectric layer and the dielectric dummy layers include different material compositions. In some embodiments, the dielectric dummy layer includes an oxide, and the second dielectric layer includes a nitride. In some embodiments, the performing of the etching process includes etching the channel members with a first etching rate and etching the dielectric dummy layers with a second etching rate, and a ratio of the first etching rate over the second etching rate ranges from about 1:3 to about 3:1.

In another exemplary aspect, the present disclosure is directed to a method. The method includes forming a fin-shaped structure protruding from a substrate, the fin-shaped structure including a plurality of channel layers interleaved by a plurality of sacrificial semiconductor layers, depositing an isolation feature on sidewalls of the fin-shaped structure, forming a dummy gate stack over a portion of the fin-shaped structure, replacing the sacrificial semiconductor layers with sacrificial dielectric layers, removing a portion of the dummy gate stack to form a trench above the portion of the fin-shaped structure, performing a first anisotropic etching process through the trench to remove the channel layers and the sacrificial dielectric layers simultaneously, performing a second anisotropic etching process to extend the trench below a bottom surface of the isolation feature, depositing an isolation structure in the trench, and replacing a remaining portion of the dummy gate stack with a metal gate structure. In some embodiments, each of the first and second anisotropic etching processes is a plasma dry etching process. In some embodiments, the first anisotropic etching process has a first ratio with respect to etching rates of the channel layers and the sacrificial dielectric layers, the second anisotropic etching process has a second ratio with respect to etching rates of the channel layers and the sacrificial dielectric layers, and the first ratio is smaller than the second ratio. In some embodiments, the first anisotropic etching process and the second anisotropic etching process each include a mixture of first and second etchants but in different ratios. In some embodiments, the first and second etchants are HBr and BCl3, respectively. In some embodiments, a bottom surface of the isolation structure has two notches.

In yet another exemplary aspect, the present disclosure is directed to a semiconductor structure. The semiconductor structure includes a plurality of nanostructures vertically stacked above a fin-shaped base protruding from a substrate, an isolation feature disposed on sidewalls of the fin-shaped base, a gate structure wrapping around each of the nanostructures, gate spacers disposed on sidewalls of the gate structure, a source/drain feature abutting the nanostructures and adjacent the gate structure, an isolation structure dividing the gate structure into two segments, an inner spacer vertically stacked between two of the nanostructures and laterally disposed between the source/drain feature and the isolation structure, and an oxide feature in contact with the inner spacer and the isolation feature. In some embodiments, a bottom portion of the isolation structure extends downwardly through the isolation feature. In some embodiments, the oxide feature is free of germanium. In some embodiments, a bottom surface of the isolation feature has two notches.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack that includes a plurality of channel layers interleaved by a plurality of sacrificial layers;
patterning the stack to form a fin-shaped structure;
forming an isolation feature on sidewalls of the fin-shaped structure;
forming a dummy gate stack over a first region of the fin-shaped structure and a top surface of the isolation feature;
depositing gate spacers on sidewalls of the dummy gate stack;
after the depositing of the gate spacers, recessing a second region of the fin-shaped structure outside of the dummy gate stack and the gate spacers to form a first trench;
selectively removing the sacrificial layers in the first region to release the channel layers as channel members;
depositing dielectric dummy layers in spaces between adjacent two of the channel members;
forming an epitaxial feature in the second region;
forming a hard mask layer above the dummy gate stack;
patterning the hard mask layer to form an opening directly above the first region of the fin-shaped structure;
performing an etching process through the opening to remove the channel members and the dielectric dummy layers in the fin-shaped structure simultaneously, such that a second trench is formed through the dummy gate stack; and
depositing an isolation structure in the second trench, wherein the isolation structure divides the dummy gate stack into two segments.

2. The method of claim 1, further comprising:
replacing the two segments of the dummy gate stack with two metal gate structures.

3. The method of claim 1, wherein the performing of the etching process extends the second trench below a bottom surface of the isolation feature.

4. The method of claim 1, further comprising:
after the performing of the etching process, performing another etching process different from the etching process to extend the second trench below a bottom surface of the isolation feature.

5. The method of claim 1, further comprising:
prior to the performing of the etching process, recessing the dummy gate stack through the opening until a gate dielectric layer of the dummy gate stack is exposed.

6. The method of claim 1, further comprising:
prior to the performing of the etching process, recessing the dummy gate stack through the opening until the fin-shaped structure is exposed.

7. The method of claim 1, further comprising:
prior to the performing of the etching process, recessing the dummy gate stack through the opening until the isolation feature is exposed.

8. The method of claim 1, wherein the forming of the isolation feature includes:
depositing a first dielectric layer on the sidewalls of the fin-shaped structure; and
depositing a second dielectric layer above the first dielectric layer, wherein the second dielectric layer and the dielectric dummy layers include different material compositions.

9. The method of claim 8, wherein the dielectric dummy layer includes an oxide, and the second dielectric layer includes a nitride.

10. The method of claim 1, wherein the performing of the etching process includes etching the channel members with a first etching rate and etching the dielectric dummy layers with a second etching rate, and wherein a ratio of the first etching rate over the second etching rate ranges from about 1:3 to about 3:1.

11. A method, comprising:
forming a fin-shaped structure protruding from a substrate, the fin-shaped structure including a plurality of channel layers interleaved by a plurality of sacrificial semiconductor layers;
depositing an isolation feature on sidewalls of the fin-shaped structure;
forming a dummy gate stack over a portion of the fin-shaped structure;
replacing the sacrificial semiconductor layers with sacrificial dielectric layers;
removing a portion of the dummy gate stack to form a trench above the portion of the fin-shaped structure;
performing a first anisotropic etching process through the trench to remove the channel layers and the sacrificial dielectric layers simultaneously;
performing a second anisotropic etching process to extend the trench below a bottom surface of the isolation feature;
depositing an isolation structure in the trench; and
replacing a remaining portion of the dummy gate stack with a metal gate structure.

12. The method of claim 11, wherein each of the first and second anisotropic etching processes is a plasma dry etching process.

13. The method of claim 11, wherein the first anisotropic etching process has a first ratio with respect to etching rates of the channel layers and the sacrificial dielectric layers, the second anisotropic etching process has a second ratio with respect to etching rates of the channel layers and the sacrificial dielectric layers, and the first ratio is smaller than the second ratio.

14. The method of claim 11, wherein the first anisotropic etching process and the second anisotropic etching process each include a mixture of first and second etchants but in different ratios.

15. The method of claim 14, wherein the first and second etchants are HBr and BCl₃, respectively.

16. The method of claim 11, wherein a bottom surface of the isolation structure has two notches.

17. A semiconductor structure, comprising:
a plurality of nanostructures vertically stacked above a fin-shaped base protruding from a substrate;
an isolation feature disposed on sidewalls of the fin-shaped base;
a gate structure wrapping around each of the nanostructures;
gate spacers disposed on sidewalls of the gate structure;
a source/drain feature abutting the nanostructures and adjacent the gate structure;
an isolation structure dividing the gate structure into two segments;
an inner spacer vertically stacked between two of the nanostructures and laterally disposed between the source/drain feature and the isolation structure; and
an oxide feature in contact with the inner spacer and the isolation feature.

18. The semiconductor structure of claim 17, wherein a bottom portion of the isolation structure extends downwardly through the isolation feature.

19. The semiconductor structure of claim 17, wherein the oxide feature is free of germanium.

20. The semiconductor structure of claim 17, wherein a bottom surface of the isolation feature has two notches.
